(19) United States
(12) Patent Application Publication
(10) Pub. No.: US 2026/0297802 A1
(43) Pub. Date: Oct. 1, 2026

(54) Relative Positioning of Crystalline Material in Crystal Growth Systems

(71) Applicant: Wolfspeed, Inc., Durham, NC (US)

(72) Inventors: Steven Herbert Griffiths, Morrisville, NC (US); Valeri Fedorovich Tsvetkov, Durham, NC (US); Adrian Roger Powell, Cary, NC (US); Caleb Andrew Kent, Durham, NC (US); Mike Paisley, Garner, NC (US); Michael Anthony Fusco, Wake Forest, NC (US); Eugene Deyneka, Cary, NC (US); Varad Rajan Sakhalkar, Cary, NC (US)

(21) Appl. No.: 19/213,646

(22) Filed: May 20, 2025

Related U.S. Application Data
(60) Provisional application No. 63/779,896, filed on Mar. 28, 2025.

(51) Int. Cl. C30B 23/02; C23C 14/06; C23C 14/24; C23C 14/50; C30B 23/06; C30B 29/36

(52) U.S. Cl. CPC C30B 23/025; C23C 14/0635; C23C 14/243; C23C 14/50; C30B 23/066; C30B 29/36

(57) ABSTRACT

An example crystalline material includes heating a source material in a crucible to transport a vapor to a crystalline material in a crystal growth process. The example crystalline material includes providing the vapor at a growth face of the crystalline material to grow crystalline material during the crystal growth process, the growth face comprising a dimension of about 100 mm. The example crystalline material includes imparting relative positioning of the growth face of the crystalline material within the crucible during the crystal growth process.

### PRIORITY CLAIM

The present application claims the benefit of priority of U.S. Provisional Application Serial No. 63/779,896, filed on Mar. 28, 2025, which is incorporated herein by reference.

### FIELD

The present disclosure relates generally to crystal growth systems, such as silicon carbide crystal growth systems for growing crystalline silicon carbide semiconductor workpieces for fabrication of semiconductor devices.

### BACKGROUND

Semiconductor devices, including power semiconductor devices based on wide bandgap materials, may be formed on a semiconductor wafer as part of a semiconductor fabrication process. Single crystal silicon carbide (SiC) has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide bandgap, high saturated electron drift velocity, high-temperature operation, and absorption and emission of high-energy photons in the blue, violet, and ultraviolet regions of the optical spectrum.

### SUMMARY

Aspects and advantages of embodiments of the present disclosure will be set forth in part in the following description, or can be learned from the description, or can be learned through practice of the embodiments.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material during the crystal growth process, the growth face comprising a dimension of about 100 mm. In some implementations, the example crystalline material includes imparting relative positioning of the growth face of the crystalline material within the crucible during the crystal growth process.

In an aspect, the present disclosure provides an example crystalline material, the crystalline material comprising silicon carbide. The system includes a crucible comprising a growth zone for the crystalline material. The system includes a positioning system configured to impart relative positioning of a growth face of the crystalline material relative to a source material within the crucible during a crystal growth process, wherein the growth face comprises a dimension of at least about 100 mm.

In an aspect, the present disclosure provides an example crystalline material. In some implementations, the example crystalline material includes a crucible at least partially defining a crystal growth chamber. In some implementations, the example crystalline material includes a seed holder configured to hold a crystalline material includes a dimension of at least about 100 mm. In some implementations, the example crystalline material includes a source material. In some implementations, the example crystalline material includes an actuator configured to impart relative movement between a growth face of a crystalline material and the source material during a crystal growth process implemented in the crystal growth chamber.

In an aspect, the present disclosure provides a crystal growth system for growing a crystalline material. In some implementations, the example crystal growth system includes a crucible at least partially defining a crystal growth chamber for growing crystalline material includes a dimension of at least about 100 mm, the crucible having a first portion and a second portion. In some implementations, the example crystalline material includes a source material in the second portion of the crucible. In some implementations, the example crystalline material includes a bearing surface between the first portion and the second portion to provide for relative movement between the first portion and the second portion during a crystal growth process.

In an aspect, the present disclosure provides an example crystalline material. In some implementations, the example crystalline material includes a crucible at least partially defining a crystal growth chamber, the crucible comprising a first zone and a second zone. In some implementations, the example crystalline material includes an interface structure between the first zone and the second zone in the crystal growth chamber. In some implementations, the example crystalline material includes an actuator configured to impart relative movement between a growth face of the crystalline material relative and the interface structure.

In an aspect, the present disclosure provides an example crystalline material. In some implementations, the example crystalline material includes a crucible at least partially defining a crystal growth chamber. In some implementations, the example crystalline material includes a seed holder configured to hold a crystalline material includes a dimension of at least about 100 mm. In some implementations, the example crystalline material includes a source material. In some implementations, the example crystalline material includes an actuator configured to move the seed holder to maintain a growth face of the crystalline material at a defined position within the crucible during a crystal growth process.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material at a first relative position in the crystal growth system. In some implementations, the example crystalline material includes imparting relative positioning of the growth face of the crystalline material to a second relative position within the crystal growth system different from the first relative position to impart a change in the growth process on the crystalline material.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material during the crystal growth process. In some implementations, the example crystalline material includes imparting relative movement of a seed holder holding the crystalline material at a pulling rate, wherein the pulling rate is based at least in part on a growth rate of the crystalline material.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material during the crystal growth process. In some implementations, the example crystalline material includes imparting relative rotational movement of the growth face of the crystalline material within the crucible relative to the source material during the crystal growth process.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a crystal growth system according to example aspects of the present disclosure.

FIGS. 2A and 2B depict a crystal growth system according to example aspects of the present disclosure.

FIGS. 3A and 3B depict a crystal growth system according to example aspects of the present disclosure.

FIGS. 4A, 4B, and 4C depict a crystal growth system according to example aspects of the present disclosure.

FIGS. 5A and 5B depict a crystal growth system according to example aspects of the present disclosure.

FIGS. 6A, 6B, and 6C depict relative positioning according to example aspects of the present disclosure.

FIGS. 7A, 7B, 7C, 7D, 7E, 7F, 7G, 7H, 7I, 7J, 7K, 7L, 7M, 7N, 7O, and 7P depict a crystal growth system according to example aspects of the present disclosure.

FIGS. 8A and 8B depict a crystal growth system according to example aspects of the present disclosure.

FIGS. 9A and 9B depict a crystal growth system according to example aspects of the present disclosure.

FIGS. 10A and 10B depict a crystal growth system according to example aspects of the present disclosure.

FIG. 11 depicts an overview of an example method according to example aspects of the present disclosure.

FIGS. 12A through 12C depict example interface structures that may be used in a crystal growth system according to examples of the present disclosure.

FIG. 13 depicts a crystal growth system according to example aspects of the present disclosure.

FIG. 14 depicts a crystal growth system according to example aspects of the present disclosure.

FIG. 15 depicts a crystal growth system according to example aspects of the present disclosure.

FIG. 16 depicts a crystal growth system according to example aspects of the present disclosure.

FIG. 17 depicts a crystal growth system according to example aspects of the present disclosure.

FIG. 18 depicts a crystal growth system according to example aspects of the present disclosure.

FIG. 19 depicts a crystal growth system according to example aspects of the present disclosure.

FIG. 20 depicts a crystal growth system according to example aspects of the present disclosure.

FIG. 21 depicts a crystal growth system according to example aspects of the present disclosure.

FIGS. 22 and 23 depict plots associated with growth rates using relative positioning according to example aspects of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to crystal growth systems (e.g., silicon carbide crystal growth systems) with relative positioning of crystalline material (e.g., relative to internal components of a crucible of the crystal growth system). Silicon carbide crystalline material may be produced using various seeded sublimation crystal growth processes. In some example silicon carbide crystal growth processes, a seed crystal and a source material are arranged in a reaction crucible which is then heated to a sublimation temperature of the source material. By controlling heating of the reaction crucible, a thermal gradient is developed between the sublimating source material and the cooler seed crystal. As a result of the thermal gradient, source material in a vapor phase is transported onto the seed crystal where it is deposited to grow a solid bulk crystalline boule. This type of sublimation crystal growth process is commonly referred to as a physical vapor transport (PVT) process.

Aspects of the present disclosure are discussed with reference to silicon carbide PVT crystal growth systems for purposes of illustration and discussion. Those of ordinary skill in the art, using the disclosures provided herein, will understand that aspects of the present disclosure may be implemented in other crystal growth systems, such as other PVT crystal growth systems.

PVT growth of, for instance, silicon carbide crystalline material may involve the sublimation and mass transport of silicon carbide (SiC) species from a silicon carbide source (e.g., powder or solid silicon carbide source) to a seed crystal. To maintain higher growth rates, the PVT crystal growth process may be performed at high temperature (e.g., greater than 1800°C) within a crucible (e.g., graphite crucible) which may be hermetically sealed or designed to maintain a specified silicon carbide vapor leak rate into a low pressure environment to maintain certain crystal growth quality metrics (e.g., low defect densities, free of crucible wall growth, etc.). These constraints may not exist in the growth of other types of crystals, such as in the growth of silicon crystals from a liquid phase material.

Crystal pulling is a technique that has been used, for instance, in the growth of silicon crystals in the liquid phase. For instance, the Czochralski method provides for silicon crystal growers to pull the crystal from the melted silicon in the liquid phase. However, the constraints of PVT crystal growth at high temperatures required to achieve desirable crystal properties in silicon carbide poses many challenges not present in growth of silicon crystals.

Aspects of the present disclosure allow for relative positioning of the growth face of a crystalline material relative to other components or selected positions in the crystal growth system (e.g., relative to other components or selected positions internal to the crucible, such as a source material or an interface structure). In some aspects, the crystal growth system may accommodate growing a crystalline material having a growth face with a largest dimension (e.g., diameter) of about 50 mm or greater, such as about 100 mm or greater, such as about 150 mm or greater, such as about 200 mm or greater, such as in a range of about 100 mm to about 300 mm, such as in a range of about 100 mm to about 200 mm. In this way, the crystal growth system may grow crystalline material boules or workpieces suitable for processing to form silicon carbide semiconductor wafers having a diameter, for instance, in a range of about 50 mm to about 300 mm, such as about 100 mm to about 200 mm, such as a semiconductor wafer having a diameter of about 50 mm, about 100 mm, about 150 mm, about 200 mm, etc.

In some embodiments, the seed crystal may be moved internally within the crucible to provide for crystal movement (e.g., crystal pulling) during the crystal growth process. Alternatively, a source material may be moved internally within the crucible to provide for relative crystal movement relative to the source material during the crystal growth process.

In some embodiments, the relative positioning may include moving the seed holder holding the crystalline material and the source material. In some embodiments, the relative positioning may be used to provide a constant mass transport distance between the growth face and the source material during the crystal growth process. In some embodiments, the relative positioning may be used to provide a variable mass transport distance that changes over time during the crystal growth process. As used herein, moving can contemplate both translational movement (e.g., movement along an axis, such an x-axis, y-axis, and/or z-axis) as well as rotational movement.

In some embodiments, relative positioning may include moving the crystalline material, source, and/or interface structure within the crucible to higher or lower temperature, flux, or pressure to change a growth process of the crystalline material. Relative positioning can include moving the crucible or other components within the crystal growth system relative to other elements (e.g., heating elements) to move the growth face of the crystalline material to different relative positions to achieve different process effects (e.g., moving to a different relative position that has higher temperature for etch back of the growth face of the crystalline material).

In some embodiments, the seed holder and/or the source material may be moved continuously for a process period. For instance, the seed holder and/or the source material may be subjected to continuous movement for a process period during a crystal growth process. The seed crystal and/or the source material may be moved at a pulling rate. The pulling rate is indicative of the displacement (e.g., distance) the seed holder or the source material is moved over time.

In some embodiments, the pulling rate may be determined based on a growth rate of the crystalline material during the crystal growth process. For instance, in some embodiments, the pulling rate may be about equal to the growth rate such that the growth face of the crystalline material remains in a nearly static position as the crystal grows. However, the pulling rate may be greater than or less than the growth rate without deviating from the scope of the present disclosure.

In some embodiments, a crystal growth system may have a system to determine the growth rate of the crystalline material in real time during a crystal growth process (e.g., using one or more in-situ sensors or by estimating the growth rate. The crystal growth system may be configured to adjust the pulling rate in real time in response to a changing growth rate to achieve selected relative positioning of the crystalline material during a crystal growth process.

In some embodiments, the relative positioning may be used to maintain or move the growth face at or to a position of selected mass transport flux in the crucible during the crystal growth process. In some embodiments, the relative positioning may be used to maintain or move the growth face at or to a position of selected temperature or temperature gradient in the crucible.

In some embodiments, the relative positioning may be used to move the growth face of the crystalline material to a first position (e.g., first vertical position in the crucible) for a first process period during a crystal growth process to achieve a certain process result (e.g., etch back of the growth face to accommodate or enhance growth of future crystalline material and/or reduce defects). The relative positioning may be used to move the growth face of the crystalline material to a second position (e.g., second vertical position in the crucible) for a second process period during a crystal growth process to achieve a second process result (e.g., growth of new crystalline material on the growth face). The second position is different than the first position. The second position may be associated with a different temperature, pressure, flux in the crystal growth system relative to the first position. The second process result may be different than the first process result. The relative positioning alternately go back and forth between moving the growth face to a first position to moving a growth face to a second position (e.g., or different third position, fourth position, etc.) during the crystal growth process to achieve selected growth characteristics of the crystalline material during the crystal growth process. Additional positions are possible relative to different processing zones (e.g., different temperature, pressure, flux, etc. withing the crucible.

Relative positioning of the growth face of the crystalline material during a crystal growth process according to examples of the present disclosure may provide a number of technical effects and benefits. For instance, relative positioning may provide for an increase in growth rates by independently controlling the relative positions and temperatures of the source and the growth face. Relative positioning of the crystalline material may lead to an increase in crystal height (e.g., no longer limited by the closed crucible volume). Relative positioning of the crystalline material may provide for a reduction of crystal stress (e.g., through improved temperature gradient control in the crystalline material). Relative positioning of the crystalline material may provide for improved process control. For instance, crystal parameters (e.g., crystal height, shape, mass, profile, etc.) may be predicted or measured and used to control relative positioning of the crystalline material to achieve selected process results and provide for dynamic process adjustment.

As used herein, crystal parameters are parameters associated with the crystalline material grown during the crystal growth process. Example crystal parameters include height, mass, shape, growth rate, doping, crystal stress, one or more optical properties, uniformity, etc., of the crystalline material during a crystal growth process. In some examples, a machine-learned model may be utilized to determine (e.g., predict) optimal process parameters to be adjusted and how much to adjust each operation parameter. As used herein, process parameters are any parameters that may be controlled during a crystal growth process to affect crystal growth. Example process parameters include temperature, pressure, coolant flow rate, flux, growth segment time duration, heater position, crucible position, crucible position relative to heater position, crystal position, source position, rotation of the crystal, etc.

In some embodiments of the present disclosure, relative positioning of the crystalline material is achieved by movement of the seed holder within the crucible. Movement of the seed holder in the crucible (e.g., as opposed to moving an entire growth zone within the crucible or moving the crucible and/or heating elements relative to the growth zone) may lead to many process advantages. For instance, moving the seed holder (e.g., holding the seed crystal and crystalline material grown on the seed holder) may provide for precise control of the vapor transport distance (e.g., distance between the growth face of the crystalline material and the source material) for the entire crystal growth process (e.g., to maintain to constant vapor transport distance or variable vapor transport distance).

In some embodiments, to provide for relative positioning in a PVT system, a crucible may include a first portion and a second portion. The first portion may include the seed holder holding the crystalline material. The second portion may include the source material. A bearing surface may be between the first portion and the second portion to allow for relative movement between the first portion and the second portion. The bearing surface may provide a flow restriction to limit or reduce vapor leak out of the crucible during the crystal growth process. In some embodiments, a loss of a crystal growth process may be determined as a ratio of the weight loss of the crucible (representative of the leak of vapor through the bearing and other loss) relative to the weight loss of the crucible plus the crystal weight. In some embodiments, the bearing surface may be configured such that the loss of the crystal growth process is less than about 20%, such as less than about 15%, such as less than about 10%. In this regard, aspects of the present disclosure may provide for relative positioning of the crystalline material during a crystal growth process for silicon carbide crystalline material while still providing high efficiency of the PVT process.

In some embodiments of the present disclosure, a crystal growth chamber may include an interface structure between the seed holder holding the crystalline material and the source material. The interface structure may be a secondary source, such as a carbon source (e.g., graphite interface structure). For instance, silicon species that are not deposited onto the crystalline material may interact with the interface structure to generate disilicon carbide or silicon dicarbide (e.g., Si₂C or SiC₂) intermediate species in the presence of a carbon-based material (e.g., the interface structure) which may enhance or provide beneficial avenues for growth kinetics, mass transport, morphology of a growing crystal, control over the growth face, and defect formation.

In some embodiments, the interface structure may be a baffle structure. The baffle structure may have one or more apertures and/or may include a porous material that allows the transport of vapor. Example baffle structures that may be used are disclosed in U.S. Patent Application Serial No. 18/962,454, filed on November 27th, 2024 which is incorporated herein by reference.

For instance, in some examples, the baffle structure includes a porous material, such as porous graphite. In some examples, at least a portion of the baffle structure has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle structure includes one or more apertures defined through a thickness of the baffle. As used herein, an “aperture” is a defined opening, space, perforation, hole, or void in a structure that extends from one exterior surface of a structure to another exterior surface of the structure. In some embodiments, the baffle has a long dimension that is generally non-perpendicular to the growth surface of the seed crystal. In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. In some examples, the one or more apertures are arranged in the baffle to provide for asymmetric vapor transport from the source material to the seed crystal. In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle.

In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure). In some examples, the baffle structure may be a secondary source or may comprise a secondary source, such as a secondary carbon source (e.g., if the interface structure comprises graphite).

The baffle structure may extend a portion or all the way across a width of a growth chamber. In some examples, the interface structure may have coating one at least a portion of one or more surfaces of the interface structure. In some examples, the coating is a pyrolytic coating. In some examples, the coating includes tantalum carbide. Other suitable coatings may be used without deviating from the scope of the present disclosure, such as other carbide coatings, such as vanadium carbide, silicon carbide, etc. Example coatings that may be used are disclosed in U.S. Application Serial No. 18/963,196, filed on November 27, 2024, U.S. Application Serial No. 18/963,136, filed on November 27, 2024, and U.S. Application Serial No. 18/963,240, filed on November 27, 2024, which are incorporated herein by reference.

In some embodiments, a coating may include metal particles and a binder that forms a matrix holding the particles together in a coating. In some embodiments, the metal may be tantalum. In some embodiments, the metal particles may be less than 10 microns in diameter. In some embodiments, the binder may be a thermally curable resin. In some embodiments, the metal particles may be functionalized with compounds that promote particle dispersion in the coating and may couple to the binder. In some embodiments, the coating is stable in air, forms a stable suspension, and can be used to dip-coat or paint parts. In some embodiments, solvent may be added to the coating, for example to tune the viscosity of the coating, tune the metal particle concentration, or tune the coating uniformity. In some embodiments, a compound that promotes sintering may be added to the coating mixture to promote sintering of the particles (e.g., at temperatures above 1000° C). The thickness of the final coating may be able to be controlled, for example by varying the concentration of metal particles in the coating and by varying the deposition volume of the coating onto the surface or part.

In some embodiments, a coating be created by applying an organometallic compound to at least one surface of a structure, wherein the at least one surface of the structure contains carbon or an oxide, curing the organometallic compound on the at least one surface of the structure; and heating the organometallic compound on the at least one surface of the structure such that the metal carbide coating is formed on the at least one surface of the structure, wherein the organometallic compound includes a central metal atom; and ligands capable of forming polydentate bonds to the central metal atom.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum. In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some examples, furanic ultra high temperatures adhesives (UHTAs) may be used as a binder in a paint that converts to a coating, such as solution processable ceramic coatings (e.g., TaC, NbC, SiC, etc.) or a non-ceramic coating (e.g., glassy carbon coatings). Certain furan functionalized compound can be used as ultra-high temperature adhesives. The chemistry of furan rings allows a broad range of furan-containing polymeric, molecular, or inorganic-organic hybrid materials that can function as UHTAs. Examples of such materials incorporating the furan heterocycle as a structural unit include: furanic polymers and resins; furanic molecules and macromolecules; furanic rigid network solids; and furan functionalized micromaterials or nanomaterials.

With the proper material design, the furanic constituents would allow these compounds to participate in crosslinking (curing) through Diels-Alder cycloaddition and the formation of a bonded glassy carbon (BGC) network. Crosslinking, which forms a three-dimensional polymeric network, can be initiated through the application of chemical, photochemical, thermal, mechanical, or electrical energy. Once cured, these materials become structurally robust solids that bind strongly to a substrate. As these cured solids are pyrolized, the furan constituents undergo ring opening and forming reactive alkene fragments ( CH2=CH2 ) and radicals which drive the formation of and condensation of polyaromatic cores resulting in a BGC network, which results in an UHTA.

The adhesion of furanic UHTAs may be further improved through the incorporation of a filler material. Use of such filler materials with UHTAs as a binding agent may be referred to as a “brick and mortar” model. Such filler materials may improve the adhesive properties of the UHTA by mechanical reinforcement. During pyrolysis of the furanic UHTA, the filler or any products generated by the chemical change of the filler may be incorporated into the network as a structural unit and mechanically strengthen the resulting bonded glassy carbon network through covalent bonding and/or strong non-covalent interactions. Such filler materials may also improve the adhesive properties of the UHTA by promoting carbon condensation. During pyrolysis of the furanic UHTA, the filler or any products generated by the chemical change of the filler may aid in the condensation of intermediate polyaromatic cores through covalent bonding and/or strong non-covalent interactions. By contributing to the condensation, a denser bonded glassy carbon network may be produced.

In some embodiments, filler materials used with furanic UHTAs may be active or may be passive. Active fillers undergo a chemical change (e.g., thermal decomposition, reduction, oxidation, solid state synthesis, etc.) into one or more products during the pyrolysis of the UHTA. Active fillers may also change aggregate state or are subject to diffusion before or during undergoing a chemical change. Passive fillers can form covalent bonds or participate in strong non-covalent interactions with the bonded glassy carbon network, but do not undergo further chemical reactions during the pyrolysis of the UHTA. Passive fillers can be impermeable or can be porous, allowing the furanic UHTA to penetrate into the material. In the case of a porous filler, the bonded glassy carbon network may form inside and outside the filler material during the pyrolysis of the UHTA. Passive fillers may participate in sintering, recrystallization, surface or bulk diffusion processes during temperature exposure. Either active or passive fillers may also create voids or porosity during temperature treatments. For example, fillers may decompose or evaporate to create voids in the UHTA.

In some examples, relative positioning of the crystalline material may include imparting relative movement between the crystalline material and the interface structure to reduce crystal stress, increase growth rate, and/or reduce heater power. For instance, in some examples, the interface structure may be moved relative to the crystalline material during a crystal growth process to provide a selected distance (e.g., fixed or variable distance) between the interface structure and the growth face of the crystalline material. In some embodiments, the crystalline material may be moved relative to the interface structure during a crystal growth process to provide a selected distance (e.g., fixed or variable distance) between the interface structure and the growth face of the crystalline material.

In some examples, imparting relative positioning of the growth face of the crystalline material relative to the source material and/or an interface structure may provide for greater than about 1.5 times the growth rate for 150 mm diameter or greater crystals, such as greater than about 2 times the growth rate, relative to crystal growth without relative positioning during the crystal growth process. Another advantage of relative positioning of the growth face of the crystalline material includes lower crucible weight loss (e.g., less weight of vapor that escapes the crucible during growth).

Yet another advantage of relative positioning of the growth face of the crystalline material includes less graphite component in a hot zone (e.g., heater component) sublimation per crystal growth run. Graphite component sublimation may be estimated, in some examples, according to an Arrhenius temperature dependence. Although higher temperatures are typically required to provide for increased growth rates, the reduction in growth time provided by relative positioning of the crystalline material according to examples of the present disclosure may reduce the total amount of graphite sublimation of heater coils per run.

Another advantage of relative positioning of the crystalline material during a crystal growth process is a removal of constraints based on a distance between a seed holder and a source material in the crystal growth system. If there is no relative positioning according to aspects of the present disclosure, the distance between the seed holder and the source material is fixed. If the crystalline material grows to an increased height that is greater than the distance between the seed holder and the source material, the crystalline material would grow into the source material. Providing for relative positioning during a crystal growth process to increase a distance between the seed holder and the source material will allow for larger crystal heights during crystal growth.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “central portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel. “Non-perpendicular” means not perpendicular.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

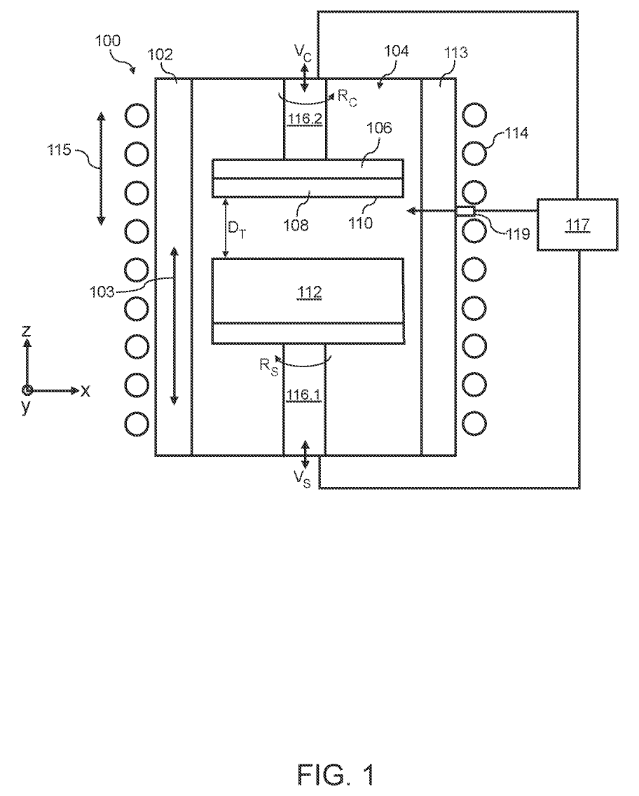

FIG. 1 is a cross-sectional schematic diagram of a crystal growth system 100 adapted for use in a crystal growth process of the type contemplated by certain embodiments of the disclosure. The crystal growth system 100 includes a reaction crucible 102 that at least partially defines a crystal growth chamber 104. The reaction crucible 102 may be, at least in part, a graphite structure. The crystal growth system 100 may further include an insulation structure 113. The insulation structure may be, for instance, a graphite structure.

A seed holder 106 may hold a seed crystal and/or a crystalline material (e.g., crystalline material silicon carbide on the seed crystal). According to examples of the present disclosure, the seed holder 106 may be configured to move and/or position a crystalline material 108 in the crystal growth system 100. The seed holder 106 may include a seed crystal, wafer, or other material. The crystalline material may be provided on the seed crystal. The crystalline material 108 may include a growth face 110 where vapor source material may be provided to grow crystalline material 108 during the crystal growth process. In some embodiments, the crystalline material 108 may be a crystalline material boule that is used to form silicon carbide semiconductor wafers, such as semiconductor wafers having a diameter in a range of about 100 mm to about 300 mm, such as about 100 mm, such as about 150 mm, such as about 200 mm.

A silicon carbide vapor source material 112 may be provided in a lower portion of the crystal growth chamber 104. During a crystal growth process, the source material 112 may be heated by one or more heaters 114 to establish a thermal gradient that sublimates the source material 112. As such, silicon carbide vapor or other vapor may be transported from the source material 112 to the growth face 110 to grow crystalline material 108 (e.g., to form a crystalline material boule). The source material 112 may be a powdered silicon carbide source material, solid silicon carbide source material, carbon and/or silicon source material, etc. Example silicon carbide source materials are disclosed in U.S. Application Serial No. 18/963,103, filed on Nov. 27, 2024, and in U.S. Application Serial No. 18/963,117, filed on Nov. 27, 2024, both of which are incorporated herein by reference.

For instance, in some examples, the silicon carbide source material includes a shaped solid silicon carbide source material structure. In some embodiments, the structure may have a composite shape. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 µm or greater, such as about 10 µm or greater, such as about 50 µm or greater, such as about 100 µm or greater, such as about 200 µm or greater, such as about 1000 µm or greater, such as about 1700 µm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

In some embodiments, a composite shaped structure may include complex geometry including shapes, features, symmetry, asymmetry, dimensions, thicknesses, and/or appendages to improve such parameters. In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated SiC. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. The source material can also be shaped to obtain a desired vapor flow/local vapor pressure relative to the seed/growing crystal surface.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature required) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the silicon carbide crystal. This is particularly useful for incorporating dopants which are not easily incorporated using a vapor source.

The crystal growth system 100 may include a positioning system, such as a source actuator 116.1 and/or a crystalline material actuator 116.2 (e.g., a first and second actuator). The crystalline material actuator 116.2 may be configured to impart relative positioning (e.g., motion) of a growth face 110 of the crystalline material 108 within the reaction crucible 102 with respect to the source material 112 during a crystal growth process, for instance, by moving the seed holder 106) holding the crystalline material in a z-direction (e.g., as indicated by arrow Vc) during a crystal growth process. Similarly, the source actuator 116.1 may be configured to impart relative positioning (e.g., motion) of the source material 112 with respect to the growth face 110 within the reaction crucible 102 during a crystal growth process, for instance, by moving the source material 112 in a z-direction (e.g., as indicated by arrow Vs) during a crystal growth process. Imparting relative positioning of the growth face 110 of the crystalline material may include moving at least one of the seed holder 106 holding the crystalline material 108 or the source material 112.

The source actuator 116.1 and/or the crystalline material actuator 116.2 may include any suitable type of actuator, such as an electric, such as an electric actuator (e.g., servo motor, stepper motor, linear motor, DC motor, AC motor, rotary motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator) and/or other suitable actuator, rotary actuator (e.g., screwing arrangement).

The source actuator 116.1 and the crystalline material actuator 116.2 may be operated independently of each other to cause relative positioning of components relative to other components. For instance, in some embodiments, the source 120 may be rotated independently of the seed holder holding the crystalline material 108. As an example, the source actuator 116.1 may be configured to impart rotational movement of the source 112 as indicated by Rs during a crystal growth process. The crystalline material actuator 116.2 may be configured to impart rotational movement of the growth face if the crystalline material 108 within the crucible as indicated by Rc during a crystal growth process.

In some embodiments, the source actuator 116.1 and the crystalline material actuator 116.2 may be configured to impart rotational movement and translational movement (e.g., in the z-direction) at the same time. For instance, one or more of the source actuator 116.1 and the crystalline material actuator 116.2 may be screw mechanisms that provide for vertical translation and rotational movement at the same time.

The source actuator 116.1 and the crystalline material actuator 116.2 are depicted as simplified schematic component blocks for ease of illustration and discussion. Those of ordinary skill in the art, using the disclosures provided herein, will understand that the source actuator 116.1 and the crystalline material actuator 116.2 may take any suitable physical and mechanical arrangement without deviating from the scope of the present disclosure.

Other components of the crystal growth system 100 may be moved without deviating from the scope of the present disclosure. For instance, as shown in FIG. 1, the heaters 114 (e.g., inductive and/or resistive heaters) may be moved in a z-direction 115 relative to the crucible 102 during a crystal growth process. In some examples, the heaters 114 may include a combination of resistive and inductive heaters and/or may be used to create one or more thermal zones. As another example, the crucible 102 may be moved in a z-direction 103 relative to the seed holder 106, source material 112, crystalline material 108, or other components during a crystal growth process.

In some embodiments, the source actuator 116.1 and/or the seed actuator 116.2 may be coupled to a control system 117 including one or more control devices (e.g., controller(s)). In some embodiments, the control devices may include one or more processors and one or more memory devices storing computer-readable instructed that when executed by the one or more processors cause the one or more processors to control aspects of the crystal growth system 100, such as the source actuator 116.1 and the seed actuator 116.2. In some embodiments, the control system 117 may be coupled to one or more sensor (e.g., x-ray sensor(s), pressure transducer(s) optical sensor(s), laser sensor(s), pyrometers, inductive sensor(s) or other suitable sensors operable to monitor process conditions and/or properties of the crystalline material (e.g., height, shape, mass, profile, etc.)) during a crystal growth process. In some embodiments, the control system 117 may be operable to control the source actuator 116.1 and the seed actuator 116.2 to move the seed holder 106 and/or the source material 112 relative to one another based on the signals from the sensor(s) 119. This may provide for dynamic control of the relative positioning of the growth face 110 of the crystalline material 108 based on process conditions or properties of the crystalline material 108, based at least in part on data from the sensor(s) 119. However, the control system 117 may control relative positioning according to aspects of the present disclosure using any suitable open loop, closed loop, or other control scheme without deviating from the scope of the present disclosure.

The control system 117 is only illustrated in FIG. 1 for illustration and discussion. The control system 117 may be used with any of the crystal growth systems provided herein without deviating from the scope of the present disclosure.

In some embodiments, the positioning system (e.g., the crystalline material actuator 116.2 and/or the source actuator 116.1) may be configured to provide a variable mass transport distance D _{T} between the source material 112 and the growth face 110 during the crystal growth process. That is, the distance D_{T} may be varied over the time as a crystal growth process progresses. In some examples, a variable mass transport distance between the source material 112 and the growth face 110 of the crystalline material 108 may become shorter over time during a crystal growth process. In some examples, a variable mass transport distance D_{T} between the source material 112 and the growth face 110 of the crystalline material 108 may become longer over time during a crystal growth process. In some examples, a variable mass transport distance D_{T} may be altered such that there is a first variable mass transport distance during a first portion of the crystal growth process, and a second variable mass transport distance during a second portion of the crystal growth process. In some examples, the distance D_{T} may be altered (e.g., shortened and/or lengthened) at differing rates during a crystal growth process.

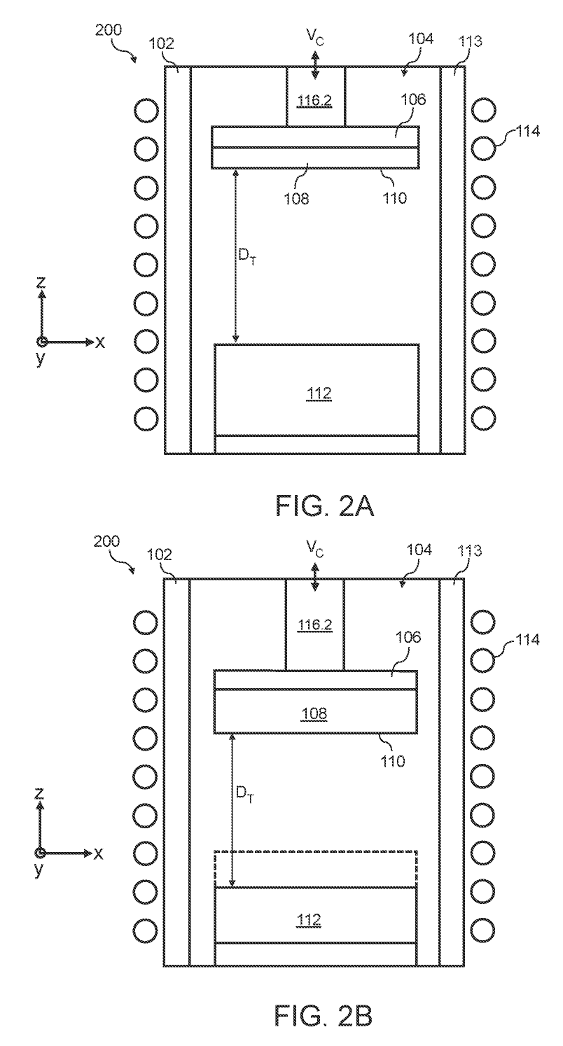

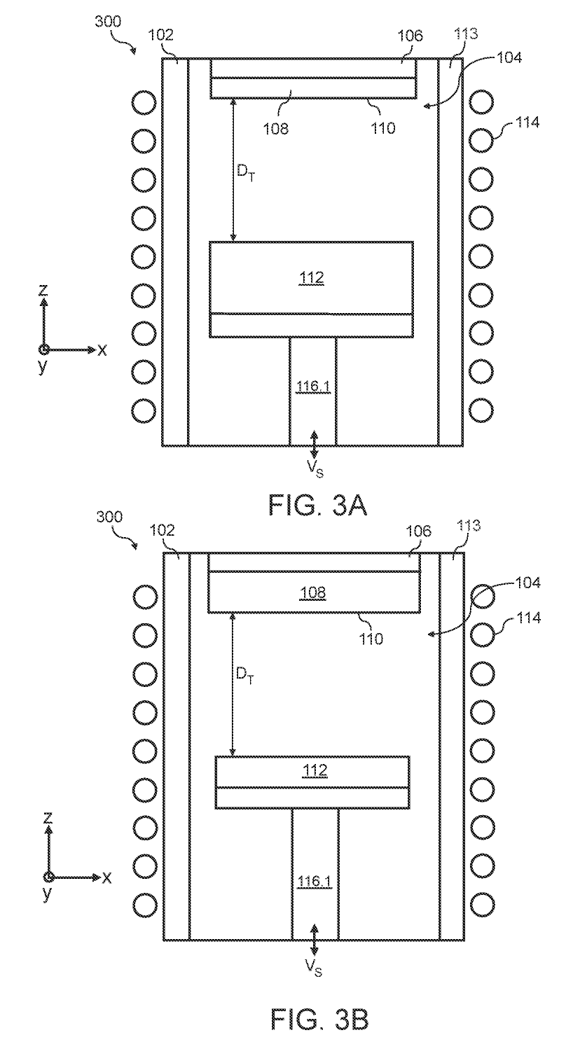

In some examples, the positioning system (e.g., the crystalline material actuator 116.2 and/or the source actuator 116.1) may be configured to provide a constant mass transport distance between the source material 112 and the growth face 110 during the crystal growth process. That is, the positioning system may be configured such that the distance D_{T} may not change during a crystal growth process. For instance, as depicted in FIGS. 2A through 3B, the mass transport distance D_{T} between the growth face 110 of the crystalline material 108 and the source material may be maintained by the positioning system to alter a position of the growth face 110 of the crystalline material 108 or the source material 112 such that the mass transport distance D_{T} remains constant, even though the crystalline material 108 grows larger during crystal growth and/or the source material 112 is depleted or etched.

FIG. 2A depicts an example crystal growth system 200 with the crystalline material actuator 116.2 at the start of a crystal growth process. FIG. 2B depicts the example crystal growth system 200 with the crystalline material actuator 116.2 at a later point in the crystal growth process. As depicted in FIG. 2B, in the crystal growth process, the crystalline material 108 may grow along the growth face 110 as the source material 112 is depleted or etched, represented by the dashed lines. The crystalline material actuator 116.2 may move the seed holder 106 and the crystalline material 108 as indicated by arrow Vc to alter a position of the growth face 110 of the crystalline material 108 relative to the source material 112 such that the mass transport distance D_{T} is constant as a crystalline material 108 grows or as the source material 112 is depleted or etched.

Similarly, FIG. 3A depicts an example crystal growth system 300 with the source material actuator 116.1 at the start of a crystal growth process. FIG. 3B depicts the example crystal growth system 300 with the source material actuator 116.1 at a later point in the crystal growth process. As depicted in FIG. 3B, the crystalline material 108 may grow along the growth face 110 as the source material 112 is depleted or etched. The source material actuator 116.1 may move the source material 112 as indicated by arrow Vs to alter a position of the source material 112 relative to the growth face 110 of the crystalline material 108 such that the mass transport distance D_{T} is constant as a crystalline material 108 grows or the source material 112 is depleted or etched.

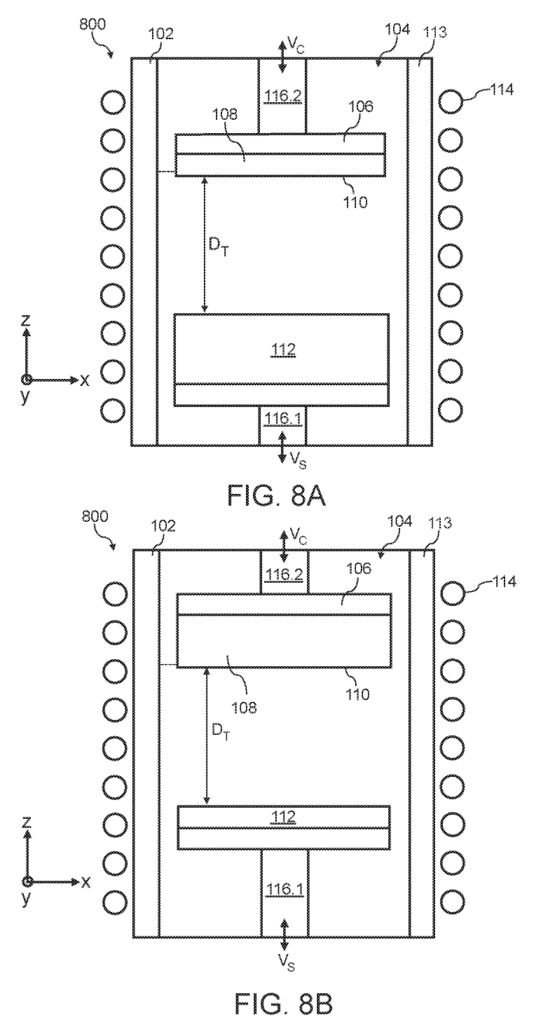

Referring again to FIG. 1, the mass transport distance D_{T} may be controlled by the positioning system (e.g., the crystalline material actuator 116.2 and/or the source material actuator 116.1) by moving the seed holder 106 holding the crystalline material 108 or by moving the source material 112 during a crystal growth process to enhance growth rate, enhance matter transport efficiency, reduce defect formation, and so forth. In some embodiments, as will be discussed in relation to FIGS. 8A to 10B, the growth face 110 of the crystalline material 108 may be optimally positioned based on temperature, vapor flux, mass transport distance D_{T}, or positioned relative to another component of the crystal growth system, such as, for instance, the one or more heaters 114.

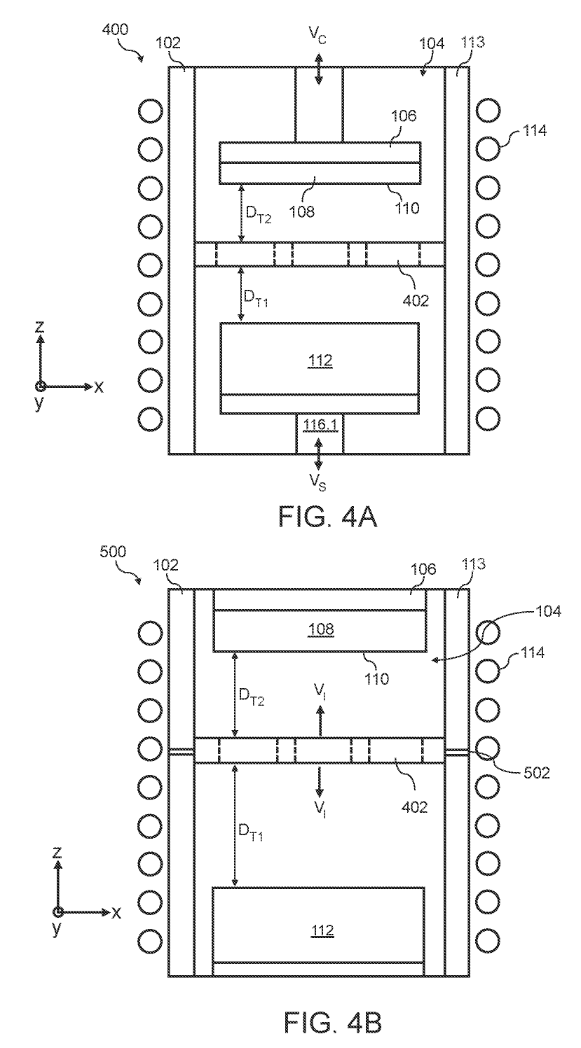

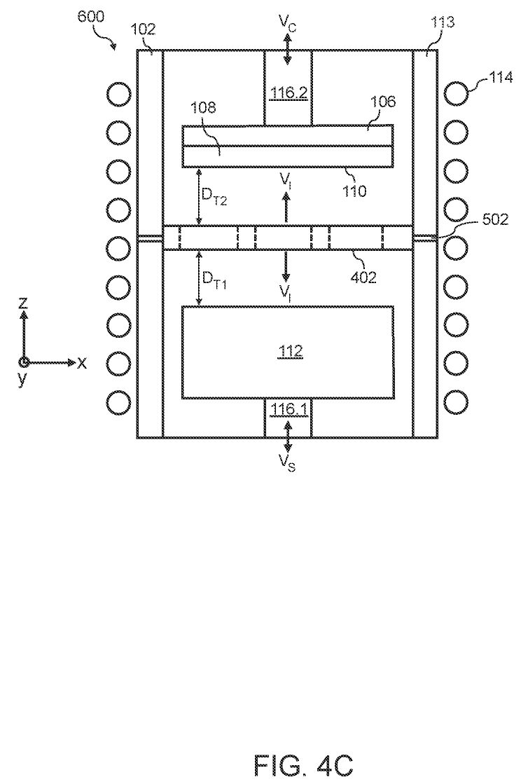

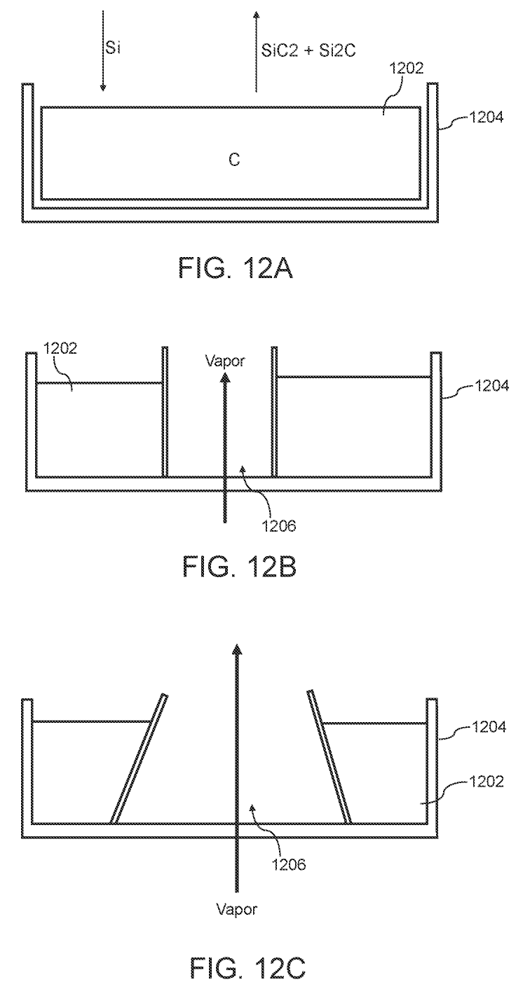

As depicted in FIG. 4A, in some examples, a crystal growth system 400 may include an interface structure 402 arranged in the vapor transport path between the growth face 110 of the crystalline material 108 and the source material 112. The interface structure may include one or more apertures or may include a porous material to allow the transport of vapor through the interface structure 402. In some examples, the interface structure 402 may include a baffle structure. Example baffle structures that may be used are disclosed in U.S. Patent Application No. 18/962,454, filed on Nov. 27th, 2024 ,which is incorporated herein by reference. In some examples, the interface structure 402 may include a secondary source material. In some examples, the interface structure 402 may be a graphite material, such as a coated graphite material. Some example interface structures 402 according to example embodiments of the present disclosure are illustrated in FIGS. 12-14. The interface structure 402 may be graphite, such as porous graphite. The interface structure 402 may include one or more apertures that assist in the transport of source vapor from the source material 120 to the crystalline material 108.

In some embodiments with an interface structure 402, the mass transport distance of FIG. 4A may be divided into a source zone distance D_{T1} and a growth zone distance D_{T2}. The source zone distance D_{T1} and the growth zone distance D_{T2} may be controlled by the positioning system (e.g., the crystalline material actuator 116.2 and/or the source material actuator 116.1). In some examples, imparting relative positioning of the growth face 110 of the crystalline material 108 during the crystal growth process includes moving at least one of the seed holder 106 holding the crystalline material 108 or the source material 112 relative to the interface structure 402. For instance, the crystalline material actuator 116.2 may move or adjust the crystalline material 108 in a positive or negative z-direction as indicated by arrow Vc to modify D_{T2} with respect to the interface structure 402. The source material actuator 116.1 may move or adjust the source material 112 in a positive direction or negative z-direction as indicated by arrow Vs to modify D_{T1}with respect to the interface structure 402. By controlling the position of the crystalline material 108 and/or the source material 112 with respect to the interface structure 402, it may be possible for a positioning system to optimize the position of the growth face 110 of the crystalline material 108, the source material 112, or the interface structure 402 during a crystal growth process to enhance growth rate, enhance matter transport efficiency (e.g., by reducing the occurrence of deposition in the crucible between the source and seed), reduce defect formation, enhance sublimation, and so forth.

As depicted in FIG. 4B, in some examples, a crystal growth system 500 may include the interface structure 402 between the growth face 110 of the crystalline material 108 and the source material 112. In some examples, imparting relative positioning of the growth face 110 of the crystalline material 108 during the crystal growth process may include moving the interface structure 402 relative to the source material 112 or the seed holder 106 holding the crystalline material 108 with an interface structure actuator 502.

Similar to the source material actuator 116.1 and the crystalline material actuator 116.2, the interface structure actuator 502 may include any suitable type of actuator, such as an electric actuator (e.g., servo motor, stepper motor, linear motor, DC motor, AC motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator), rotary actuator, and/or other suitable actuator. Those of ordinary skill in the art, using the disclosure provided herein, will understand that any type of actuator may be used to move components without deviating from the scope of the present disclosure.

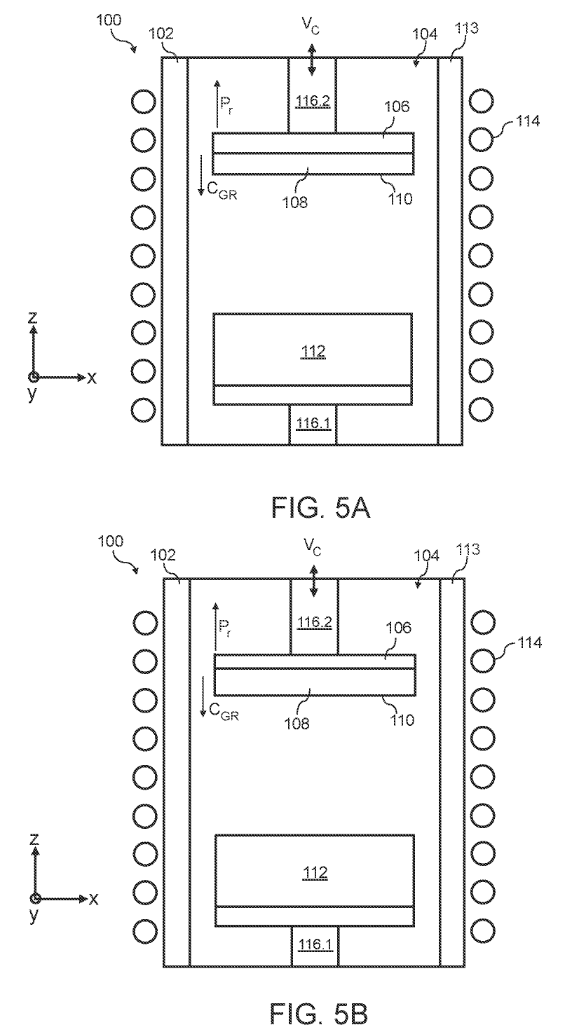

The mass transport distance of FIG. 4B may be divided into the source zone distance D_{T1} and the growth zone distance D_{T2}. The source zone distance D_{T1} and the growth zone distance D_{T2} may be provided by the positioning system (e.g., the interface structure actuator 502). In some examples, imparting relative positioning of the growth face 110 of the crystalline material 108 during the crystal growth process includes moving the interface structure 402 with respect to at least one of the seed holder 106 holding the crystalline material 108 or the source material 112. For instance, using the reference frame provided with FIG. 5, the interface structure actuator 502 may move or adjust the interface structure 402 in a negative or a positive z-direction as indicated by arrows V_{I} to modify D_{T1} and/or D_{T2}. By controlling the relative position of the interface structure 402 with respect to the to the growth face 110 of the crystalline material 108 or the source material 112, it may be possible for a positioning system to optimize the position of the growth face 110 of the crystalline material 108, the source material 112, or the interface structure 402 during a crystal growth process to enhance growth rate, enhance matter transport efficiency, reduce defect formation, enhance sublimation, and so forth.

As depicted in FIG. 4C, a crystal growth system 600 may include the interface structure 402 between the growth face 110 of the crystalline material 108 and the source material 112. In some examples, imparting relative positioning of the growth face 110 of the crystalline material 108 during the crystal growth process includes moving at least one of the seed holder 106 holding the crystalline material 108, the source material 112, and/or the interface structure 402. For instance, the crystalline material actuator 116.2 may move or adjust the crystalline material 108 in a negative or a positive z-direction as indicated by arrow Vc to modify D_{T2} with respect to the interface structure 402. The source material actuator 116.1 may move or adjust the source material 112 in a negative or a positive z-direction as indicated by arrow Vs to modify D_{T1} or D_{T2} with respect to the interface structure 402. The interface structure actuator 502 move or adjust the interface structure 402 in a negative or a positive z-direction as indicated by arrows V_{I} to modify D_{T1} or D_{T2} By controlling the relative positioning of the crystalline material actuator 116.2, the source material actuator 116.1, and/or the interface structure actuator 502 with respect to the growth face 110 of the crystalline material 108, it may be possible for a positioning system to optimize the position of the growth face 110 of the crystalline material 108, the source material 112, or the interface structure 402 during a crystal growth process to enhance growth rate, enhance matter transport efficiency, reduce defect formation, enhance sublimation, and so forth.

In some embodiments, relative positioning can include imparting relevant movement of the growth face of the crystalline material at a pulling rate. The pulling rate is the displacement of the seed holder over time and is indicative of the rate at which the seed holder is moved. For instance, FIGS. 5A and 5B depict imparting relative positioning in a crystal growth system similar to FIG. 1 by moving a seed holder 106 at a pulling rate Pr. FIG. 5A depicts the crystal growth system at a first time and FIG. 5B depicts the crystal growth system at a second later time. As shown in FIGS. 5A and 5B, the seed holder 106 is moved (e.g., by actuator 116.2) at a pulling rate Pr.

In some embodiments, the pulling rate Pr is based at least in part on the crystal growth rate C_{GR}. For instance, the seed holder 106 is moved or pulled at a certain rate that achieves desired crystal growth effects based on the crystal growth rate C_{GR}. In some embodiments, the pulling rate Pr is about the same as the crystal growth rate C_{GR} such that the growth face 100 of the crystalline material is maintained in about the same position during the crystal growth process, as indicated by FIG. 5B. However, in some embodiments, the pulling rate Pr may be greater than or less than the crystal growth rate C_{GR}. In some embodiments, a crystal growth process may include determining a change in crystal growth rate C_{GR} during the crystal growth process (e.g., using the one or more sensors 119 of FIG. 1). The pulling rate Pr may be adjusted based at least in part on the change in crystal growth rate C_{GR.}

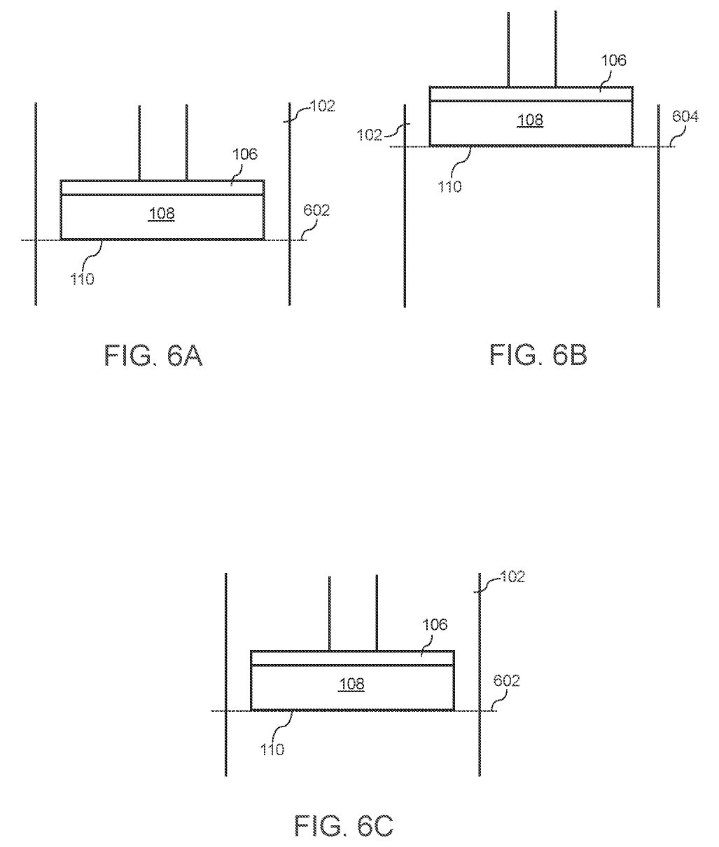

FIGS. 6A, 6B, and 6C depict a simplified representation of relative positioning of a growth face 110 of a crystalline material 108 within a crucible 102 according to example embodiments of the present disclosure. For instance, FIG. 6A depicts imparting relative positioning of the growth face 110 of the crystalline material 108 to a first position 602 within the crucible 102 for a first process period. The first position 602 may be associated with, for instance, a first temperature. It will be understood that the first position 602 may be associated with another reactor component or process parameter, such as the insulation structure 113 of FIG. 1, the interface structure 402 of FIGS. 4A through 4C, or, for instance, with a mass flow (flux) or transport distance as discussed herein. The first position 602 may be used to achieve a certain process result (e.g., etch back of the growth face to accommodate or enhance growth of future crystalline material). FIG. 6B depicts imparting relative positioning of the growth face 110 of the crystalline material 108 to a second position 604 within the crucible 102 for a second process period. The second position may be associated with, for instance, a second temperature (e.g., less than the first temperature). The second position 604 may be used to achieve a certain process result (e.g., optimize crystal growth). It will be understood that the second position 604 may be associated with another reactor component or process parameter, such as the insulation structure 113 of FIG. 1, the interface structure 402 of FIGS. 4A through 4C, or, for instance, with a mass flow or a transport distance as discussed herein.

The relative positioning may alternately go back and forth between moving the growth face 110 to the first position 602 to moving a growth face to the second position 604 (e.g., or different third position, fourth position, etc.) during the crystal growth process to achieve selected growth characteristics of the crystalline material 108 during the crystal growth process. For instance, FIG. 6C depicts imparting relative positioning of the growth face 110 of the crystalline material 108 back to the first position 602 within the crucible 102 for a third process period. Aspects of the present disclosure may be used to position the growth face 110 of the crystalline material 108 at various different positions within the crucible 102 for different process periods without deviating from the scope of the present disclosure to achieve various crystal growth effects.

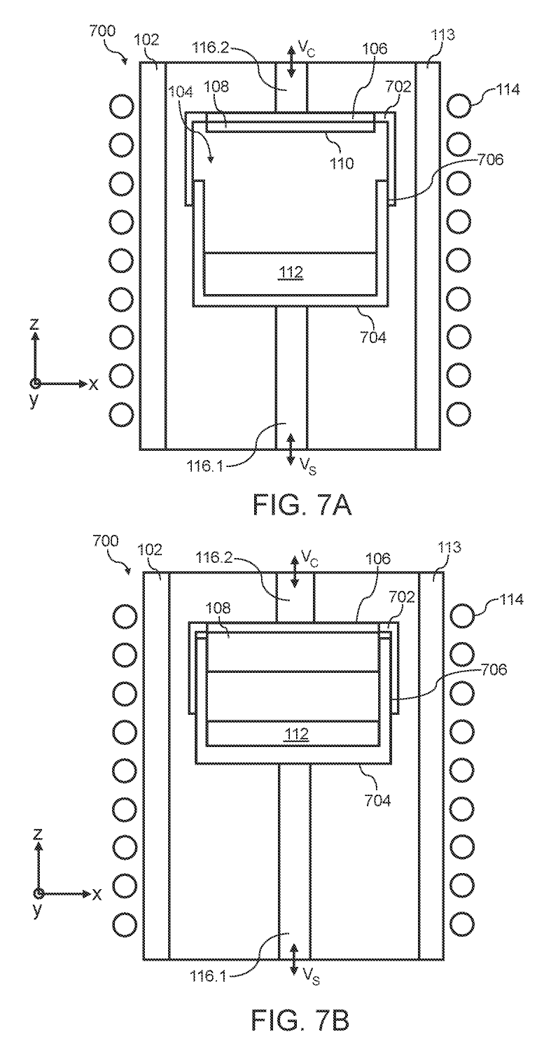

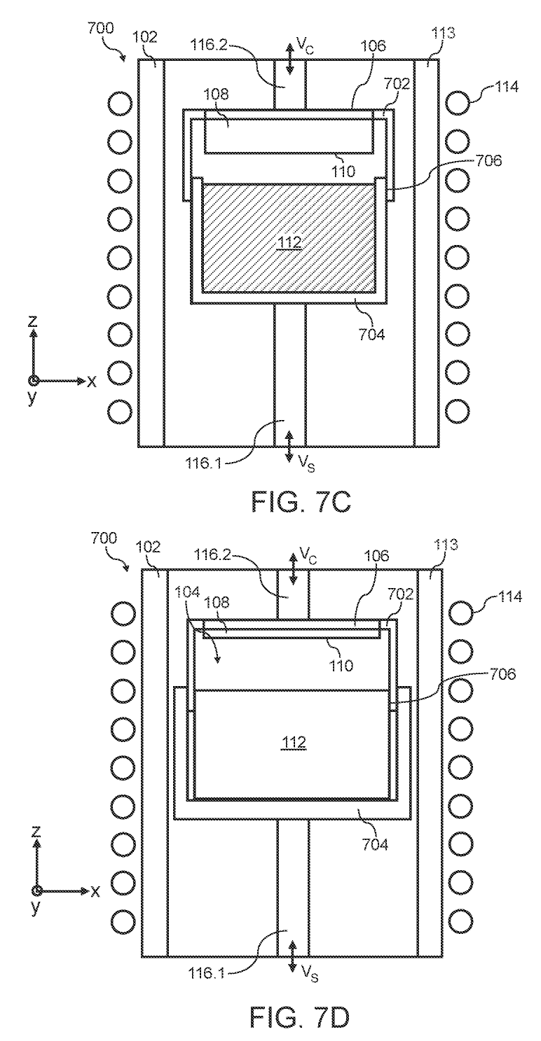

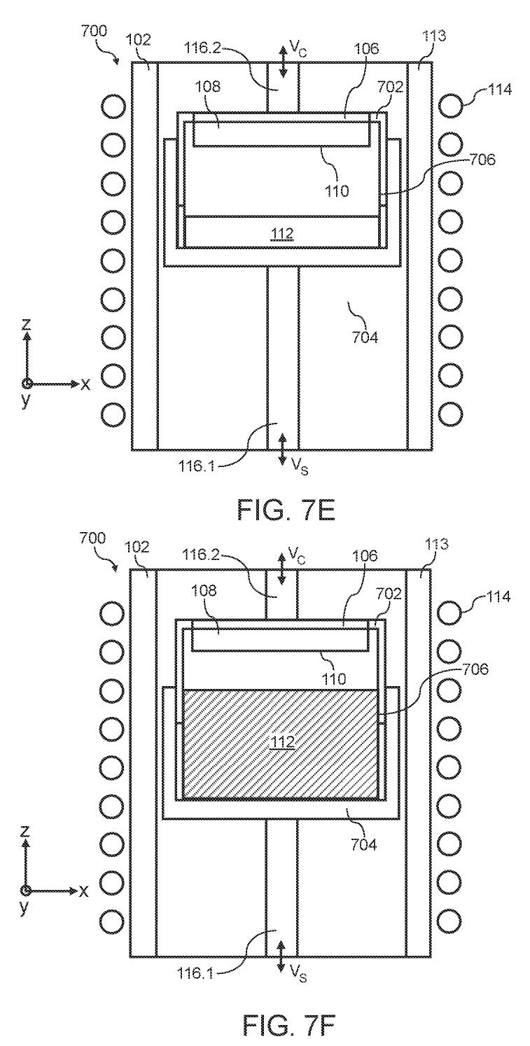

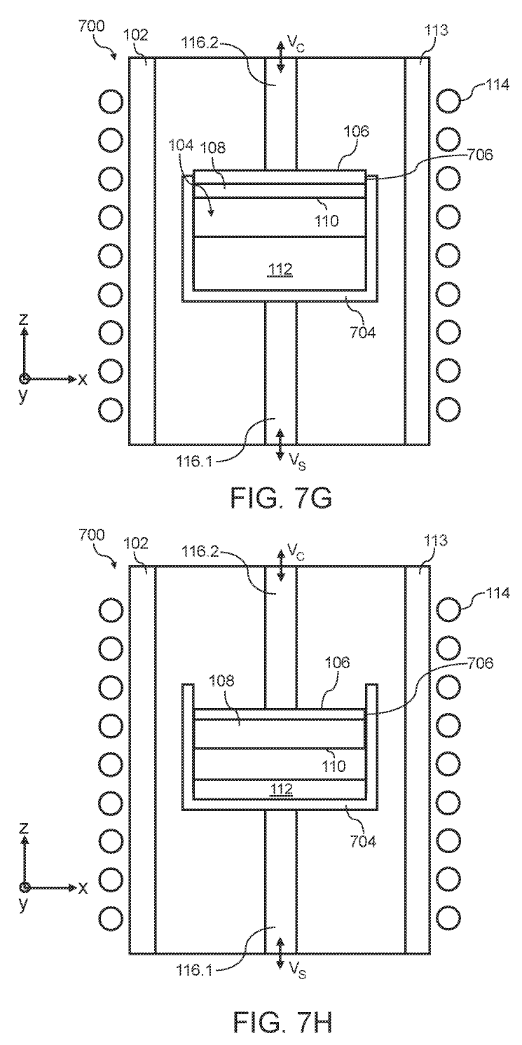

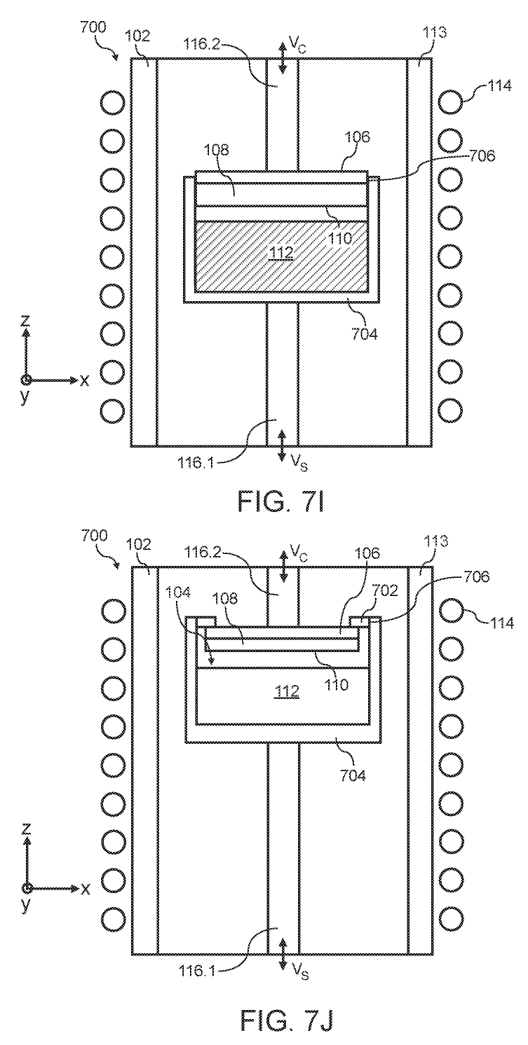

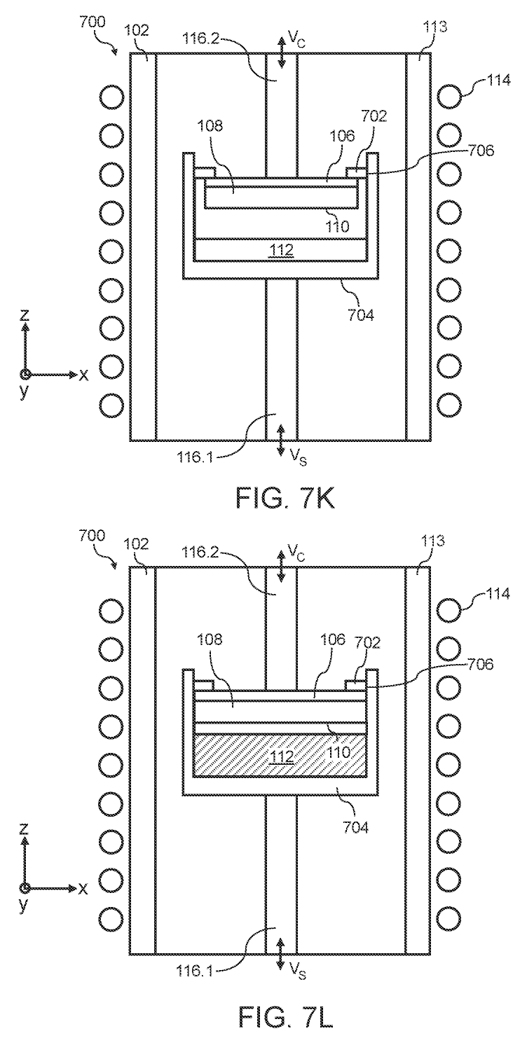

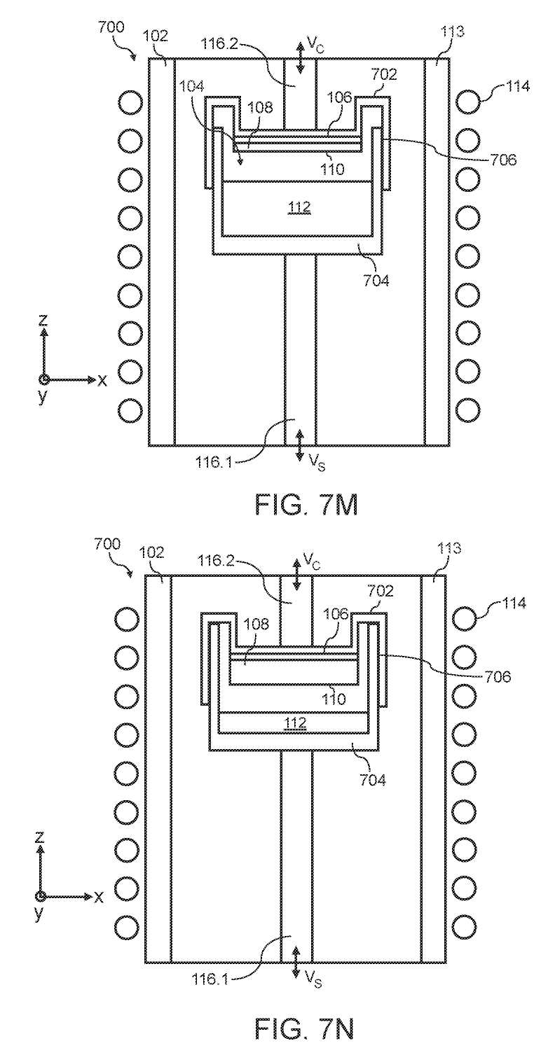

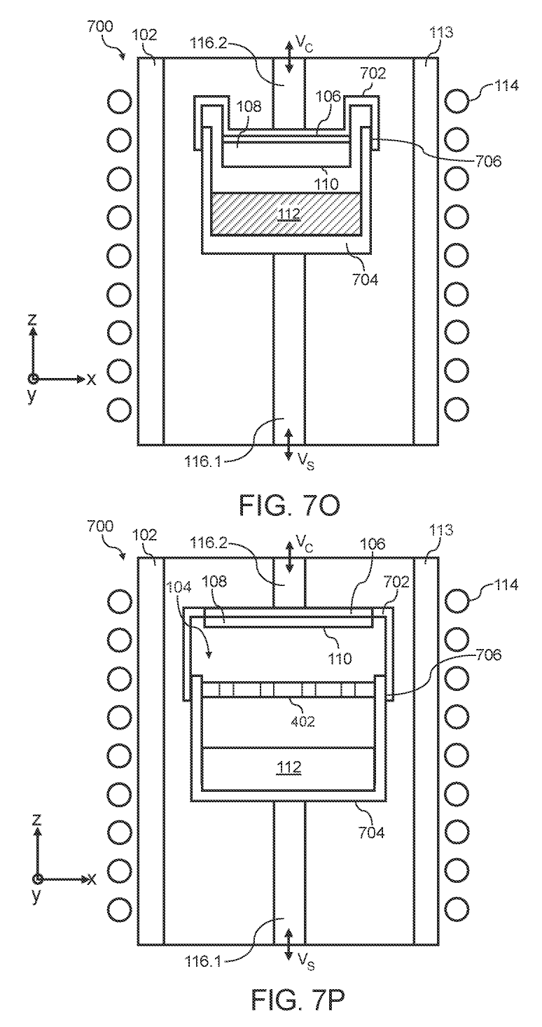

FIG. 7A is a cross-sectional schematic diagram of a crystal growth system 700 adapted for use in a crystal growth process of the type contemplated by certain embodiments of the disclosure. The crystal growth system 700 may include many of the components of FIGS. 1 through 6C, such as the reaction crucible 102, the seed holder 106, the crystalline material 108 with the growth face 110, the source material 112, the one or more heaters 114, the source material actuator 116.1 and the crystalline material actuator 116.2.

As depicted in FIG. 7A, the reaction crucible 102 may include a first portion 702 associated with the crystalline material 108. The growth face 110 of the crystalline material 108 may be positioned within the first portion 702 of the reaction crucible 102 (e.g., provided by the seed holder 106). The reaction crucible 102 may include a second portion 704 associated with the source material 112 such that the second portion 704 includes the source material 112. The first portion 702 and the second portion may define the crystal growth chamber 104.

As depicted in FIG. 7A, the first portion 702 may include one or more vertical members that define an inner diameter of the first portion 702. The first portion 702 may be configured to accommodate one or more vertical members of the second portion 704 that define an outer diameter of the second portion 704. That is, the second portion 704 may be configured to move in a positive or negative z-direction within the first portion 702. Similarly, the first portion 702 may be configured to move in a positive or negative z-direction around the second portion 704.

The crystal growth system 700 may include a bearing surface 706 between the first portion 702 and the second portion 704 (e.g., at the inner diameter of the first portion 702 and an outer diameter of the second portion 704). The bearing surface 706 may be a linear bearing surface. The bearing surface 706 may be provided such that the first portion 702 and the second portion 704 may move along a positive or negative z-direction in the reaction crucible 102 while restricting vapor or other fluid leaking out of the crystal growth chamber during the crystal growth process. More particularly, the bearing surface 706 may have a size adapted to provide a mass transport restriction out of the crystal growth chamber such that a loss of vapor source material through the bearing surface is restricted. The bearing surface 706 with mass transport restriction may allow for efficient PVT-based crystal growth processes while also providing the advantages of relative positioning of crystalline material 108 according to example aspects of the present disclosure. The mass transport restriction of source vapor out of the crucible 102 provided by the bearing surface 706 may be such that a loss associated with the crystal growth process is less than about 20%, such as less than about 15%, such as less than about 10%.

As depicted in FIG. 7B, at least one of the first portion 702 or the second portion 704 may move in a positive or negative z-direction as a volume of the source material 112 is depleted in a crystal growth process. The alteration to the z-direction position of the source material 112 or the growth face 110 of the crystalline material 108 may alter the process environment to enhance crystal growth and mitigate variation at the growth face 110 of the crystalline material 108 during a crystal growth process.

FIG. 7C depicts another example crystal growth system according to example embodiments of the present disclosure. As depicted in FIG. 7C, the source material 112 may not be depleted in volume, but may be altered by the crystal growth process. For instance, the preferential sublimation of silicon from a silicon carbide source material may selectively remove silicon from the source material 112 such that a carbon material structure remains in the second portion 704.

Other suitable configurations and bearing surfaces may be used without deviating from the scope of the present disclosure. For instance, as depicted in FIG. 7D, the first portion 702 may have an outer diameter that is configured to accommodate an inner diameter of the second portion 704 such that the second portion 704 may be configured to move in a positive or negative z-direction with the first portion 702 within. Similarly, the first portion 702 may be configured to move in a positive or negative z-direction around the second portion 704. A bearing surface 706 (e.g., linear bearing surface) is provided between the first portion 702 and the second portion 704. The first portion 702 and the second portion may define the crystal growth chamber 104.

As depicted in FIG. 7E, at least one of the first portion 702 or the second portion 704 may move in a positive or negative z-direction as a volume of the source material 112 is depleted in a crystal growth process. The alteration to the z-direction position of the source material 112 or the growth face 110 of the crystalline material 108 may alter the process environment to enhance crystal growth and mitigate variation at the growth face 110 of the crystalline material 108 during a crystal growth process.

FIG. 7F depicts another example crystal growth system according to example embodiments of the present disclosure. As depicted in FIG. 7F, the source material 112 may not be depleted in volume, but may be altered by the crystal growth process. For instance, the preferential sublimation of silicon from a silicon carbide source material may selectively remove silicon from the source material 112 such that a carbon material structure remains in the second portion 704.

Other suitable configurations and bearing surfaces may be used without deviating from the scope of the present disclosure. For instance, as depicted in FIG. 7G, the seed holder 106 or other component may act as the first portion 702. The seed holder 106 may have a diameter that is configured to accommodate an inner diameter of the second portion 704 such that the second portion 704 may be configured to move in a positive or negative z-direction with the seed holder 106 within. Similarly, the seed holder 106 may be configured to move in a positive or negative z-direction within the second portion 704. The bearing surface 706 (e.g., linear bearing surface) is provided between the seed holder 106 and the second portion 704. The first portion 702 and the second portion may define the crystal growth chamber 104.

As depicted in FIG. 7H, at least one of the seed holder 106 or the second portion 704 may move in a positive or negative z-direction as a volume of the source material 112 is depleted in a crystal growth process. The alteration to the z-direction position of the source material 112 or the growth face 110 of the crystalline material 108 may alter the process environment to enhance crystal growth and mitigate variation at the growth face 110 of the crystalline material 108 during a crystal growth process.

FIG. 7I depicts another example crystal growth system according to example embodiments of the present disclosure. As depicted in FIG. 7F, the source material 112 may not be depleted in volume, but may be altered by the crystal growth process. For instance, the preferential sublimation of silicon from a silicon carbide source material may selectively remove silicon from the source material 112 such that a carbon material structure remains in the second portion 704.

Other suitable configurations and bearing surfaces may be used without deviating from the scope of the present disclosure. For instance, as depicted in FIG. 7J, the first portion 702 may have a diameter that is configured to accommodate an inner diameter of the second portion 704 such that the second portion 704 may be configured to move in a positive or negative z-direction with the first portion 702 within. Similarly, the first portion 702 may be configured to move in a positive or negative z-direction around the second portion 704. The first portion 702 may or may not extend across a majority of the seed holder 106. A bearing surface 706 (e.g., linear bearing surface) is provided between the first portion 702 and the second portion 704. The first portion 702 and the second portion may define the crystal growth chamber 104.

As depicted in FIG. 7K, at least one of the first portion 702 or the second portion 704 may move in a positive or negative z-direction as a volume of the source material 112 is depleted in a crystal growth process. The alteration to the z-direction position of the source material 112 or the growth face 110 of the crystalline material 108 may alter the process environment to enhance crystal growth and mitigate variation at the growth face 110 of the crystalline material 108 during a crystal growth process.

FIG. 7L depicts another example crystal growth system according to example embodiments of the present disclosure. As depicted in FIG. 7F, the source material 112 may not be depleted in volume, but may be altered by the crystal growth process. For instance, the preferential sublimation of silicon from a silicon carbide source material may selectively remove silicon from the source material 112 such that a carbon material structure remains in the second portion 704.

Other suitable configurations and bearing surfaces may be used without deviating from the scope of the present disclosure. For instance, as depicted in FIG. 7M, the first portion 702 may include one or more vertical members extending in a z-direction that are connected by a horizontal section that extends in an x-direction. The vertical members and the horizontal section of the first portion may define a recess region. The first portion 702 may include an inner diameter that is configured to accommodate an outer diameter of the second portion 704 such that the second portion 704 may be configured to move in a positive or negative z-direction within the recess region defined by the vertical members of the first portion 702. Similarly, the first portion 702 may be configured to move in a positive or negative z-direction around the second portion 704. A bearing surface 706 (e.g., linear bearing surface) is provided between the first portion 702 and the second portion 704. The first portion 702 and the second portion may define the crystal growth chamber 104.

As depicted in FIG. 7N, at least one of the first portion 702 or the second portion 704 may move in a positive or negative z-direction as a volume of the source material 112 is depleted in a crystal growth process. The alteration to the z-direction position of the source material 112 or the growth face 110 of the crystalline material 108 may alter the process environment to enhance crystal growth and mitigate variation at the growth face 110 of the crystalline material 108 during a crystal growth process.

FIG. 7O depicts another example crystal growth system according to example embodiments of the present disclosure. As depicted in FIG. 7F, the source material 112 may not be depleted in volume, but may be altered by the crystal growth process. For instance, the preferential sublimation of silicon from a silicon carbide source material may selectively remove silicon from the source material 112 such that a carbon material structure remains in the second portion 704.

An optional interface structure may be included in any of the crystal growth systems of FIGS. 7A-7O. The interface structure may be similar to the interface structure 402 of FIG. 4A. The interface structure may extend at least a portion or all the way across a flux path or portion of the crucible. In some examples, the interface structure may be moved with either the first portion or the second portion of the crucible. In some examples, the interface structure may be moved independently of the first portion or the second portion.

For instance, FIG. 7P depicts a crystal growth system 700 having an interface structure 402 on the second portion 704 and can be moved with the second portion 704 according to examples of the present disclosure. The interface structure may also be located on the first portion 702 or independent of the first portion 702 and the second portion 704 without deviating from the scope of the present disclosure.

FIG. 8A and 8B are cross-sectional schematic diagrams of a crystal growth system 800 adapted for use in a crystal growth process of the type contemplated by certain embodiments of the disclosure. The crystal growth system 800 may include many of the components of FIGS. 1 through 7, such as the reaction crucible 102, the seed holder 106, the crystalline material 108 with the growth face 110, the source material 112, the one or more heaters 114, the source material actuator 116.1 and the crystalline material actuator 116.2.

FIG. 8A depicts the example crystal growth system 800 with the crystalline material actuator 116.2 at the start of a crystal growth process. FIG. 8B depicts the example crystal growth system 800 with the crystalline material actuator 116.2 at a second position at a later point in the crystal growth process. The source material actuator 116.2 may adjust a z-direction position of the source material 112 over the course of a crystal growth process, as depicted in FIGS. 8A and 8B. Over the course of the crystal growth process the growth face 110 of the crystalline material 108 may be positioned with respect to a z-direction position on the sidewall (e.g., an insulation material) of the reaction crucible 102. That is, the z-direction position of the growth face 110 of the crystalline material 108 may be configured to be positioned at a defined point (e.g., as represented by the dashed line) relative to one or more of the insulation structures 113. In the example depicted in FIGS. 8A and 8B, the growth face 110 is depicted as being positioned by the crystalline material actuator 116.2 such that the defined point remains constant between differing points in time of the crystal growth process (e.g., a first time in FIG. 8A and a second time in FIG. 8B). In this way, the positioning system (e.g., the source material actuator 116.1 or the crystalline material actuator 116.2) may be configured to maintain the growth face 110 at a position or defined point of a selected vapor flux, a selected temperature, or other parameter in the crucible 102.

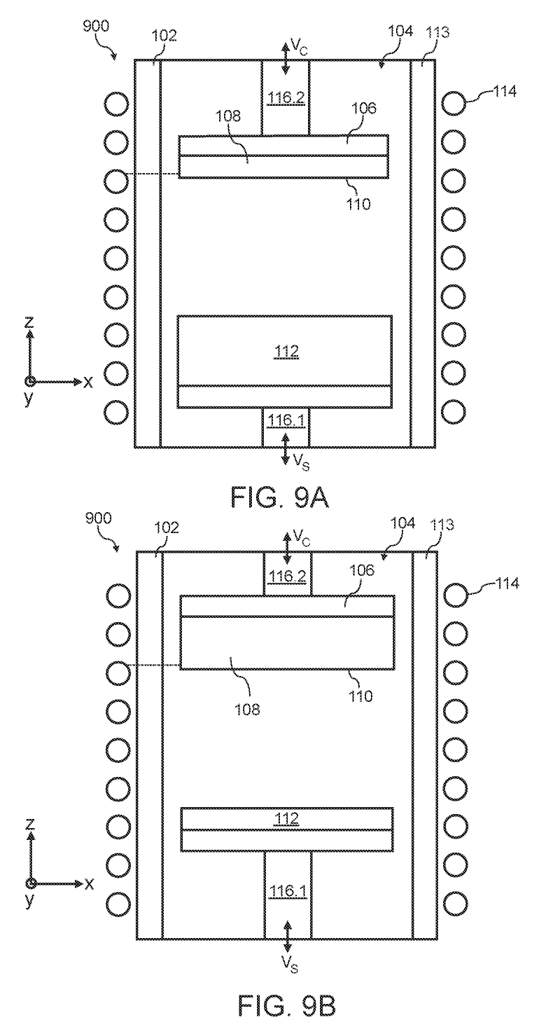

FIG. 9A and 9B are cross-sectional schematic diagrams of a crystal growth system 900 adapted for use in a crystal growth process of the type contemplated by certain embodiments of the disclosure. The crystal growth system 900 may include many of the components of FIGS. 1 through 8B, such as the reaction crucible 102, the seed holder 106, the crystalline material 108 with the growth face 110, the source material 112, the one or more heaters 114, the source material actuator 116.1 and the crystalline material actuator 116.2.

FIG. 9A depicts the example crystal growth system 900 with the crystalline material actuator 116.2 at the start of a crystal growth process. FIG. 9B depicts the example crystal growth system 800 with the crystalline material actuator 116.2 at a second position at a later point in the crystal growth process. The source material actuator 116.2 may adjust a z-direction position of the source material 112 over the course of a crystal growth process, as depicted in FIGS. 9A and 9B. Over the course of the crystal growth process the growth face 110 of the crystalline material 108 may be configured to be positioned with respect to a z-direction position of the one or more heaters 114 of the reaction crucible 102. That is, the z-direction position of the growth face 110 of the crystalline material 108 may be configured to be positioned at at a defined point (e.g., as represented by the dashed line) from the one or more heaters 114. In the example depicted in FIGS. 9A and 9B, the growth face 110 is depicted as being positioned by the crystalline material actuator 116.2 such that the defined point remains constant between differing points in time of the crystal growth process (e.g., a first time in FIG. 9A and a second time in FIG. 9B). In this way, the positioning system (e.g., the source material actuator 116.1 or the crystalline material actuator 116.2) may be configured to maintain the growth face 110 at a position or defined point of a selected vapor flux, a selected temperature or other parameter in the crucible 102.

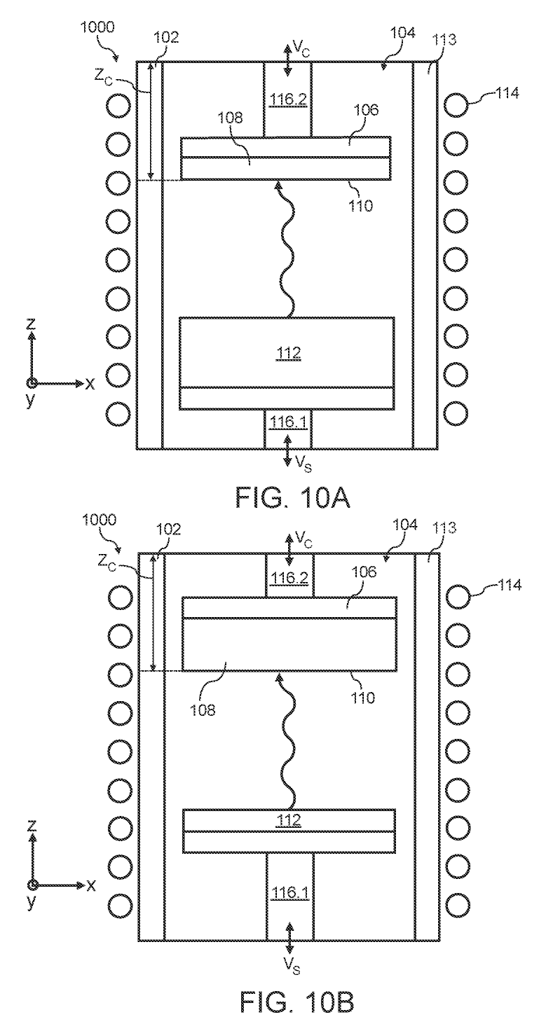

FIG. 10A and 10B are cross-sectional schematic diagrams of a crystal growth system 1000 adapted for use in a crystal growth process of the type contemplated by certain embodiments of the disclosure. The crystal growth system 1000 may include many of the components of FIGS. 1 through 9B, such as the reaction crucible 102, the seed holder 106, the crystalline material 108 with the growth face 110, the source material 112, the one or more heaters 114, the source material actuator 116.1 and the crystalline material actuator 116.2.

FIG. 10A depicts the example crystal growth system 1000 with the crystalline material actuator 116.2 at the start of a crystal growth process. FIG. 10B depicts the example crystal growth system 1000 with the crystalline material actuator 116.2 at a second position at a later point in the crystal growth process. The source material actuator 116.2 may adjust a z-direction position of the source material 112 over the course of a crystal growth process, as depicted in FIGS. 9A and 9B. Over the course of the crystal growth process, the growth face 110 of the crystalline material 108 may be configured to be positioned with respect to a z-direction position of a selected vapor flux F, represented by a curved arrow. That is, the z-direction position of the growth face 110 of the crystalline material 108 may be configured to be positioned at the defined distance Z_{c} where concentration and rate of source vapor transported over an area is controlled. In the example depicted in FIGS. 10A and 10B, the growth face 110 is depicted as being positioned by the crystalline material actuator 116.2 at the defined distance Z_{c} that remains constant between differing points in time of the crystal growth process (e.g., a first time in FIG. 10A and a second time in FIG. 10B). In this way, the positioning system (e.g., the source material actuator 116.1 or the crystalline material actuator 116.2) may be configured to maintain the growth face 110 at a position or defined distance Z_{c} of a selected vapor flux and/or a selected temperature in the crucible 102.

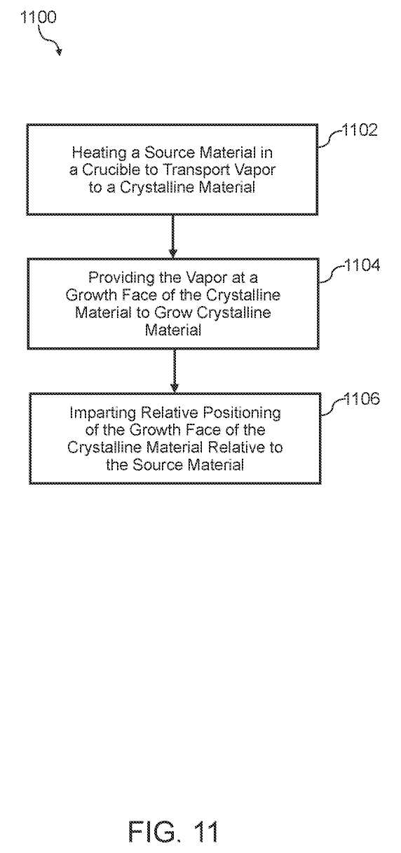

FIG. 11 provides an overview of an example method 1100 for growing crystalline material (e.g., crystalline silicon carbide) in a crystal growth system, according to examples of the present disclosure. FIG. 11 may be implemented by any of the crystal growth systems provided in the present disclosure or other crystal growth system. FIG. 11 depicts operations performed in a particular order for purposes of illustration and discussion. Those of ordinary skill in the art, using the disclosures provided herein, will understand that the various operations of any of the methods provided herein may be adapted, expanded, rearranged, omitted, include steps not illustrated, or modified in various ways without deviating from the scope of the present disclosure.

At 1102, the method 1100 may include heating a source material in a crucible to transport vapor to a crystalline material in a crystal growth process. In some embodiments, the source material may be heated to temperatures of about 1200° C to about 3000° C, such as about 1800° C. to 3000° C., such as about 1800° C. to about 2500° C., such as about 1800° C. to about 2000° C., such as about 2000° C. to about 2200° C.. Heating the source material may cause the source material to sublime to provide vapor that forms on crystalline material on a seed crystal.

At 1104, the method 1100 may include providing a vapor at a growth face of the crystalline material to grow crystalline material during the crystal growth process. In some embodiments, a thermal gradient in the crystal growth system may encourage vapor transport from the source material to the growth face of a crystalline material (e.g., seed crystal) followed by deposition on the growth face resulting in crystal growth during a crystal growth process.

Typically, the growth face may be heated to a temperature in a range from about 1200° C. to about 3000° C., such as about 1800° C. to 3000° C., such as about 1800° C. to about 2500° C., such as about 1800° C. to about 2000° C., such as about 2000° C. to about 2200° C.. In some embodiments, the temperature of the growth face is less than a temperature of the source material.

During a crystal growth process, a reaction crucible may be evacuated slowly to reduce pressure. In some embodiments, crystal growth may be performed at a pressure in a range from about 0.1 torr to about 50 torr, such as about 0.1 torr to about 25 torr, such as about 0.1 torr to about 15 torr, such as about 1 torr to about 15 torr, among other pressure ranges. Growth temperatures and growth pressures may generally vary with one another. For example, depending on the growth conditions, higher growth temperatures may be associated with higher growth pressures or lower growth temperatures may be associated with lower growth pressures. By maintaining the source material and the growth surface of the crystalline material at their respective temperatures for a sufficient time, macroscopic growth crystalline material (e.g., monocrystalline silicon carbide) of a selected polytype may form upon the growth face.

At 1106, the method includes imparting relative positioning of the growth face of the crystalline material according to examples of the present disclosure, such as discussed with reference to FIGS. 1-10A. Imparting relative positioning may occur during operations 1102 and 1104. In some embodiments, imparting relative positioning includes moving at least one of a seed holder holding the crystalline material or the source material. Imparting relative positioning of the growth face of the crystalline material may include moving the source material relative to the growth face of the crystalline material. Imparting relative positioning of the growth face of the crystalline material may include moving a seed holder holding the crystalline material relative to the source material.

In some embodiments imparting relative positioning of the growth face of the crystalline material during the crystal growth process may include maintaining a constant mass transport distance between the source material and the growth face during the crystal growth process. Imparting relative positioning of the growth face of the crystalline material during the crystal growth process may include providing a variable mass transport distance between the source material and the growth face during the crystal growth process. Imparting relative positioning of the growth face of the crystalline material during the crystal growth process may include maintaining the growth face at a position of selected vapor flux during the crystal growth process. Imparting relative positioning of the growth face of the crystalline material during the crystal growth process may include maintaining the growth face at a position of selected temperature in the crucible.

FIGS. 12A-12C depict example interface structures 402 that may be used in a crystal growth system according to examples of the present disclosure, such as the crystal growth systems depicted in FIGS. 4, 5, and 6. The interface structures 402 of FIGS. 12A-12C are secondary sources and include a carbon source. The interface structures 402 may enhance a crystal growth process by providing intermediate species for crystal growth. For instance, silicon species that are not deposited onto the crystalline material may interact with the interface structure 402 to generate disilicon carbide or silicon dicarbide (e.g., Si₂C or SiC₂) intermediate species in the presence of a carbon-based material. The intermediate species may be provided to the growth face of a crystalline material for crystal growth.

In the example of FIG. 12A, the interface structure 402 includes a carbon structure 1202 in a coating dish structure 1204. The carbon structure 1202 may be graphite, such as a porous graphite (e.g., graphite with a porosity greater than about 70%, such as greater than about 80%). The carbon structure 1202 may be depleted or etched during a crystal growth process. The coating dish structure 1204 may be on three sides of the carbon structure 1202 but may leave a surface of the carbon structure 1202 facing the growth face exposed.

In some examples, the coating dish structure 1204 is a pyrolytic coating. In some examples, the coating includes tantalum carbide. Other suitable coatings may be used without deviating from the scope of the present disclosure, such as other carbide coatings, such as vanadium carbide, silicon carbide, etc. Example coatings that may be used are disclosed in U.S. Application Serial No. 18/963,196, filed on Nov. 27, 2024, U.S. Application Serial No. 18/963,136, filed on Nov. 27, 2024, and U.S. Application Serial No. 18/963,240, filed on Nov. 27, 2024, which are incorporated herein by reference as discussed above.

FIG. 12B discloses an interface structure 402 that is similar to the interface structure of FIG. 12A. However, the interface structure 402 includes an aperture 1206 extending through a center of the interface structure 402 that allows for mass transport of vapor from a source material to a growth face during a crystal growth process. The sidewalls of the aperture 1206 are generally parallel to the direction of vapor flow.

FIG. 12C depicts an interface structure 402 that is similar to the interface structure of FIG. 12C. The interface structure 402 of FIG. 12C includes an aperture 1206 extending through a center of the interface structure 402 that allows for mass transport of vapor from a source material to a growth face during a crystal growth process. The sidewalls of the aperture 1206 are not generally parallel to the direction of vapor flow. For instance, the sidewalls may be angled inward. The direction of the sidewalls may be in any configuration without deviating from the scope of the present disclosure.

In some embodiments, the design of the interface structure 402 (e.g., the interface structures 402 of FIGS. 12A to 12C) may be used to provide enough vapor flow to a center of a growth face of the crystalline material. To maintain high growth rates, and as discussed with reference to FIGS. 4, 5, and 6, it may be desirable to precisely control a distance between the growth face of the crystalline material and the interface structure 402.

In some embodiments, a solid phase density of the carbon structure 802 (e.g., graphite) of the interface structure 402 may be less than a solid phase density of the crystalline material (e.g., silicon carbide) grown on the growth face. In this regard, the carbon structure may lose thickness faster relative to a growing thickness of crystalline material. Accordingly, relative positioning of the growth face relative to the interface structure according to example embodiments of the present disclosure may be used to maintain a constant distance (or other variable distance as selected) during a crystal growth process.

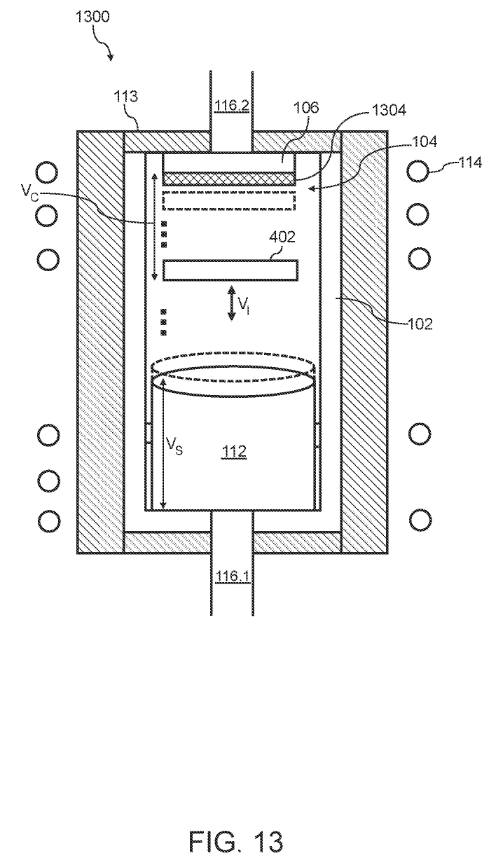

FIG. 13 is a cross-sectional schematic diagram of a crystal growth system 1300 adapted for use in a crystal growth process of the type contemplated by certain embodiments of the disclosure. The crystal growth system 1300 includes the reaction crucible 102, the interior of which defines the crystal growth chamber 104. The crystal growth system 1300 includes the heater 114 adapted to heat the reaction crucible 102. Alternatively, a resistive heating approach may be applied to the heating of the reaction crucible 102. Using any competent heating mechanism and approach, the temperature within the crystal growth system 1300 may be controllable. The reaction crucible 102 may be, at least in part, a graphite structure.

The crystal growth system 1300 may also include one or more gas inlet and gas outlet ports and associated equipment allowing the controlled introduction and evacuation of gas from an environment surrounding the reaction crucible 102. The introduction and evacuation of various gasses to or from the environment surrounding the reaction crucible 102 may be accomplished using a variety of inlets/outlets, pipes, valves, pumps, gas sources, and controllers. It will be further understood by those skilled in the art, using the disclosures provided herein, that the crystal growth system 1300 may further incorporate in certain embodiments a water-cooled quartz vessel.

The reaction crucible 102 may be surrounded by the insulation material 113. The composition, size, and placement of the insulation material 113 may vary with an individual crystal growth system to define and/or maintain selected temperature profile (e.g., both axially and radially) in relation to the reaction crucible 102.

Prior to establishment of the temperature profile, the reaction crucible 102 is loaded with the source material 112 (e.g., silicon carbide vapor source material, such as a silicon carbide powder or solid silicon carbide source). As such, the reaction crucible 102 includes one or more portions, at least one of which is capable of providing the source material 112. The source material 112 may be held in a lower portion of the reaction crucible 102, as is common for one type of crystal growth system, such as the crystal growth system 1300 of FIG. 13.

A seed crystal 1304 may be placed above or in an upper portion of the reaction crucible 102. The seed crystal 1304 may take the form of a silicon carbide seed wafer having a diameter, for instance, from about 50 mm to about 310 mm or greater. A silicon carbide crystalline material may be grown from the seed crystal 1304 during a crystal growth process.

In the embodiment illustrated in FIG. 13, the seed holder 106 is used to hold the seed crystal 1304. The seed holder 116 may be positioned in an upper portion of the reaction crucible 102 to hold the seed crystal 1304 in a selected position. In some embodiments, the seed holder 116 is fabricated from carbon (e.g., graphite). The attachment of the seed crystal 1304 (e.g., a seed wafer) to the seed holder 106 within the crystal growth system 1300 may be made, for instance, by a uniform thermal contact. Various techniques may be used to implement a uniform thermal contact. For example, the seed crystal 1304 may be placed in direct physical contact with the seed holder 106, or an adhesive may be used to fix the seed crystal 1304 to the seed holder 116, so as to provide uniform conductive and/or radiative heat transfer over substantially the entire area between the seed crystal 1304 and the seed holder 106.

The crystal growth system 1300 may include the interface structure 402. The interface structure 402 may provide a mechanism for transport of source vapor or other process gas during sublimation of the source material 112. The interface structure 402 may filter or otherwise reduce impurities from the source material 112 that may inadvertently sublimate in a crystal growth process. The interface structure 402 may provide for control radiative heat transfer. The interface structure 402 may act as a secondary source material.

As depicted in FIG. 13, the crystal growth system 1300 may include the source actuator 116.1. As represented by the arrow V_{S}, a z-direction position of the source material 112 may be altered in a crystal growth process. Similarly, the crystal growth system 1300 may include the crystalline material actuator 116.2. As represented by the arrow V_{C}, a z-direction position of the seed crystal 1304 (e.g., the growth face of a growing crystalline material) may be altered in a crystal growth process. As represented by the arrow V_{I}, a z-direction position of the interface structure 402 may be altered in a crystal growth process.

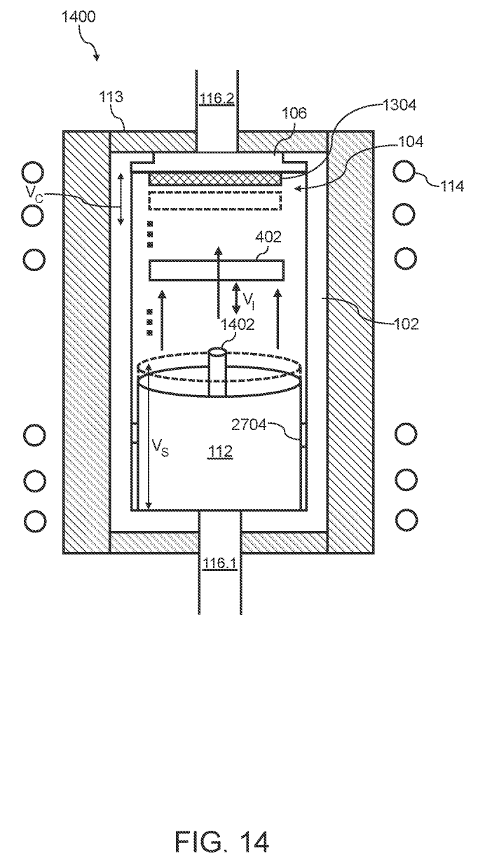

In one example embodiment, shown in FIG. 14, the crystal growth system 1400 may be similar to that shown in FIG. 13, but may also include an inlet 1402 for introducing a dopant (e.g., N₂) to the reaction crucible 102. The inlet 1402, may be, for example, a tube, pipe, vent, or the like. In some embodiments, the source material 112 may surround the inlet 1402. For example, in some embodiments, the source material 112 may include a channel through which the inlet 1402 is provided. In other embodiments, the source material 112 may include a plurality of subcomponents (attached or detached) which surround the inlet 1402. The inlet 1402 may be connected to a dopant-containing gas source (not shown) and configured to introduce the dopant-containing gas to the reaction crucible 102. An example of a dopant-containing gas is nitrogen.

The crystal growth system 1400 may include the interface structure 402402 that may be situated within the reaction crucible 102. The interface structure 402 may provide a mechanism for the transport of source vapor during sublimation of the source material 112. The interface structure 402 may have any spatial orientation relative to the source material 112, the seed crystal 1304, and/or the reaction crucible 102. The interface structure 402 may filter or otherwise reduce impurities from the source material 112 that may inadvertently sublimate in a crystal growth process. The interface structure 402 may provide for control of radiative heat transfer.

As shown in FIG. 14, the interface structure 402 may be located on the source material, may be spaced apart from the source material 112 and/or the seed crystal 1304, or may be proximate to the seed crystal 1304. In some embodiments, the system 1400 may include any number of interface structures 402 without deviating from the scope of the present disclosure. In some embodiments, the source material 112 may have the interface structure 402 or baffle element incorporated therein.

As depicted in FIG. 14, the crystal growth system 1400 may include the source actuator 116.1. As represented by the arrow V_{S}, a z-direction position of the source material 112 may be altered in a crystal growth process. Similarly, the crystal growth system 1400 may include the crystalline material actuator 116.2. As represented by the arrow V_{C}, a z-direction position of the seed crystal 1304 (e.g., the growth face of a growing crystalline material) may be altered in a crystal growth process. As represented by the arrow V_{I}, a z-direction position of the interface structure 402 may be altered in a crystal growth process.

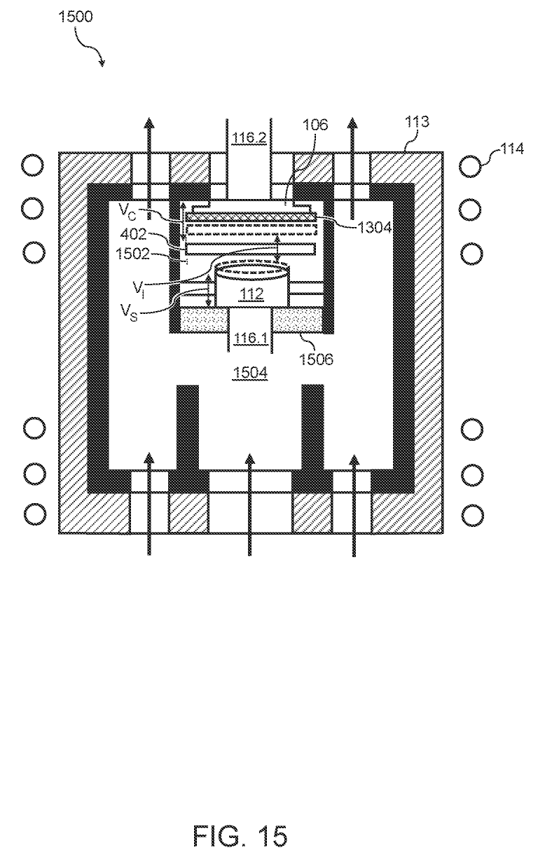

In another example embodiment, shown in FIG. 15, the crystal growth system 1500 may be a continuous feed PVT (CF-PVT) system. In a CF-PVT system, such as the crystal growth system 1500 of FIG. 15, the reaction crucible 102 may include an upper chamber 1502 and a lower chamber 1504. The upper chamber 1502 may include the source material 112 and the seed crystal 1304. The upper chamber 1502 may be separated from the lower chamber 1504 by a foamed structure 1506. The foamed structure 1506 may be formed, for example, from a gas-permeable graphite foam. The source material 112 may be placed on the foamed structure 1506 within the upper chamber 1502. A gaseous silicon source (e.g., trimethylsilane diluted in argon) may be supplied to the lower chamber 1504. As the gaseous silicon source is transported through the foamed structure 1506, it may react with a carbon source within the foamed structure 1506 (e.g., graphite) to form silicon carbide. A CF-PVT system, such as the crystal growth system 1500 of FIG. 15, combines a PVT process for the growth of single crystals and high temperature chemical vapor deposition (HTCVD) processes for the in-situ formation and continuous feeding of a high purity polycrystalline source. A CF-PVT system, such as the crystal growth system 1500 of FIG. 15, may be particularly useful for growing 3C silicon carbide.

The crystal growth system 1500 may include the interface structure 402 that may be situated within the upper chamber 1502 of the reaction crucible. The interface structure 402 may provide a mechanism for the transport of source vapor during sublimation of the source material 112. The interface structure 402 may filter or otherwise reduce impurities from the source material 112 that may inadvertently sublimate in a crystal growth process. The interface structure 402 may provide for control over radiative heat transfer. The interface structure 402 may have any spatial orientation relative to the source material 112, the seed crystal 1304, and/or the upper chamber 1502 of the reaction crucible.

As depicted in FIG. 15, the crystal growth system 1500 may include the source actuator 116.1. As represented by the arrow V_{S}, a z-direction position of the source material 112 may be altered in a crystal growth process. Similarly, the crystal growth system 1500 may include the crystalline material actuator 116.2. As represented by the arrow V_{C}, a z-direction position of the seed crystal 1304 (e.g., the growth face of a growing crystalline material) may be altered in a crystal growth process. As represented by the arrow V_{I}, a z-direction position of the interface structure 402 may be altered in a crystal growth process.

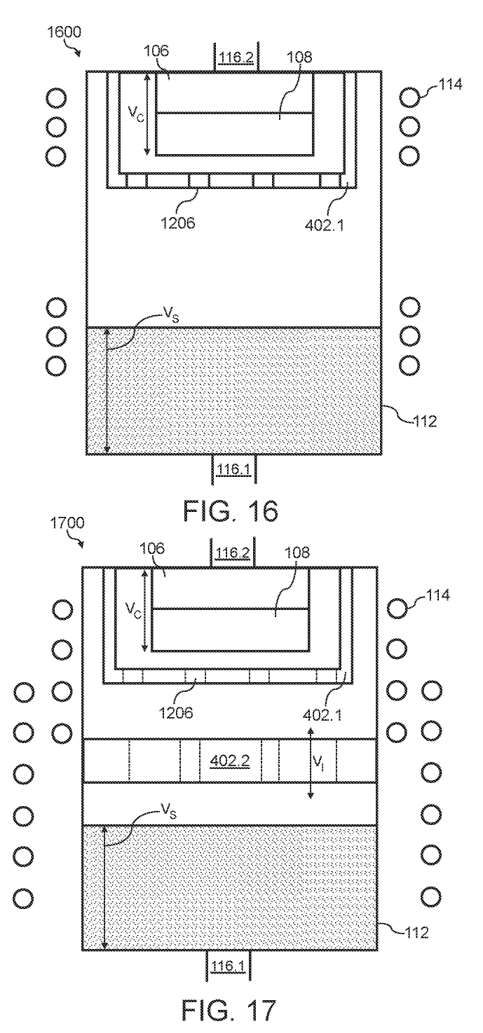

FIGS. 16 and 17 depict an example crystal growth system 1600, 1700 according to example embodiments of the present disclosure. In FIG. 16, the crystal growth system 1600 may include the interface structure 402.1, the seed holder 106, the crystalline material 108, and the source material 120. The interface structure 402.1 may be positioned such that the interface structure 402.1 extends around at least three sides of the crystalline material 108, with the longest dimension located below the crystalline material 108. The interface structure 402.1, in this configuration, may be referred to as a shell structure as it provides a shell around the crystalline material 108. The interface structure 402.1 may be graphite, such as porous graphite. The interface structure 402.1 may include one or more apertures 1206 that assist in the transport of source vapor from the source material 112 to the crystalline material 108. The interface structure 402.1 may include a baffle structure. In some examples, the interface structure 402.1 may or may not include any apertures 1206. The interface structure 402.1 may be porous graphite and may have a porosity of greater than about 70%. The interface structure 402.1 may be positioned such that the interface structure 402.1 extends around at least three sides of the crystalline material 108, with the longest dimension located below the crystalline material 108.

As depicted in FIG. 17, the system 1700 may include one or more second interface structure(s) 402.2. The one or more second interface structure(s) 1202.2 may be arranged in the vapor transport path from the source material 112 to the crystalline material 108. The one or more second interface structure(s) 402.2 may be graphite, such as porous graphite. The interface structure 402.2 may include a baffle structure. The interface structure 402.2 may include one or more apertures 1206.

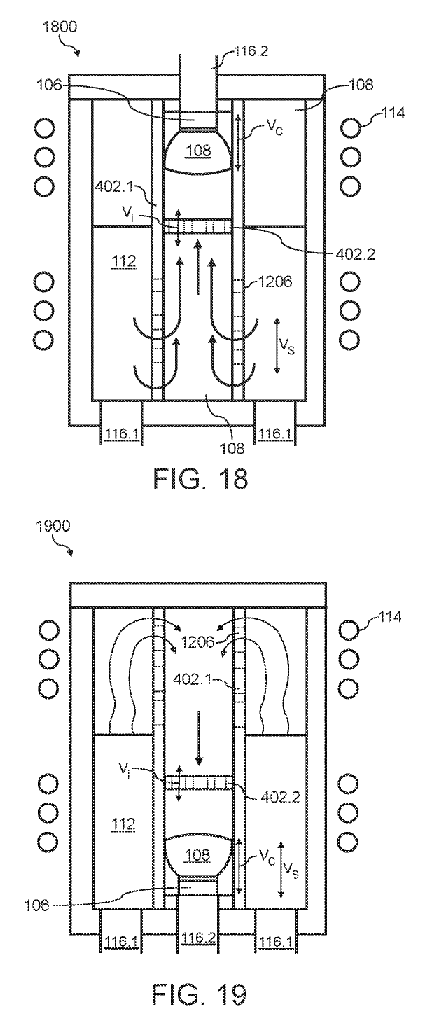

In FIG. 18, the crystal growth system 1800 may include the interface structure 402.1, the seed holder 106, the crystalline material 108, and the source material 112. The interface structure 402.1 may include a tubular baffle structure. The crystalline material 108 may be within the interface structure 402.1. The interface structure 402.1 may be graphite, such as porous graphite. The interface structure 402.1 may include one or more apertures 1206 that assist in the transport of source vapor from the source material 112 to the crystalline material 108. The system 1800 may further include one or more second interface structures 402.2. The one or more second interface structures 402.2 may be arranged in the vapor transport path between the source material 120 and the crystalline material 108. Source vapor may be transported through the interface structures 402.1 and 402.2. The one or more second interface structure(s) 402.2 may be graphite, such as porous graphite. The interface structure 402.2 may include a baffle structure. The interface structure 402.2 may include one or more apertures.

In FIG. 19, the crystal growth system 1900 includes the crystalline material 108 at the top of the crucible. Similar to FIG. 18, the interface structure 402.1 may include a tubular baffle structure. The crystalline material 108 may be within the interface structure 402.1. The interface structure 402.1 may be graphite, such as porous graphite. The interface structure 402.1 may include one or more apertures 1206 that assist in the transport of source vapor from the source material 112 to the crystalline material 108. The system 1900 may further include one or more second interface structures 402.2. The one or more second interface structures 402.2 may be arranged in the vapor transport path between the source material 112 and the crystalline material 108. Source vapor may be transported through the interface structures 402.1 and 402.2. The one or more second interface structure(s) 402.2 may be graphite, such as porous graphite. The interface structure 402.2 may include a baffle structure. The interface structure 402.2 may include one or more apertures 1206.

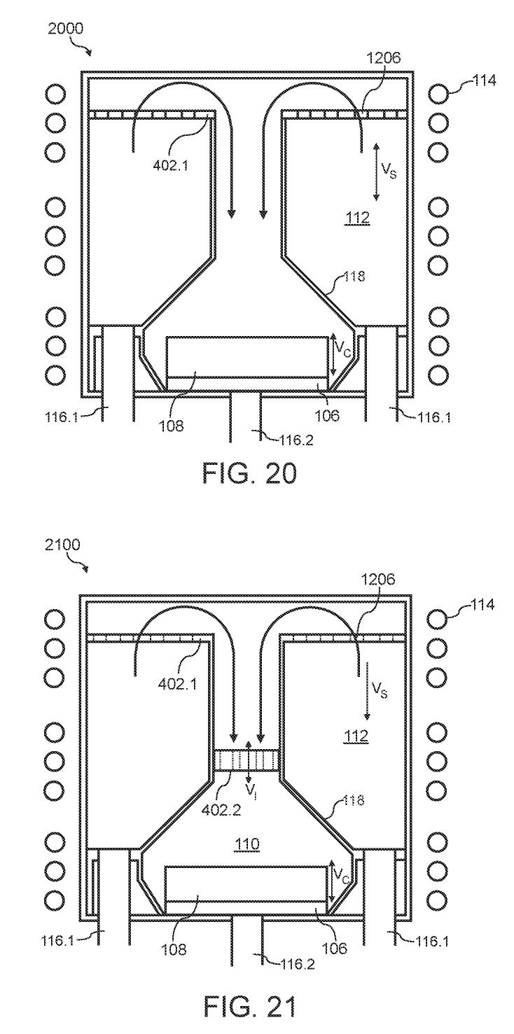

FIG. 20 depicts an example crystal growth systems 2000 according to example embodiments of the present disclosure. In FIG. 20, the crystal growth system 2000 includes the seed holder 106 and the crystalline material 108 arranged within the crucible 118. The crucible 118 may have one or more angled sidewalls. The crystal growth system 2000 includes a source material 112. The interface structure 402.1 may be on top of the source material 112 and may separate the source material 112 from the reaction chamber defined by the crucible 118. As depicted in FIG. 20, the interface structure 402.1 may include one or more apertures 1206 to assist with vapor transport from the source material 112 to the crystalline material 108.

As depicted in FIG. 21, the crystal growth system 2100 may include one or more second interface structures 402.2. The interface structure(s) 402.2 may be arranged in the vapor transport path between the source material 112 and the crystalline material 108. Source vapor may be transported through the interface structure 402.1 and/or the interface structure 402.2. The one or more second interface structure(s) 402.2 may be graphite, such as porous graphite. The interface structure 402.2 may include a baffle structure. The interface structure 402.2 may include one or more apertures 1206.

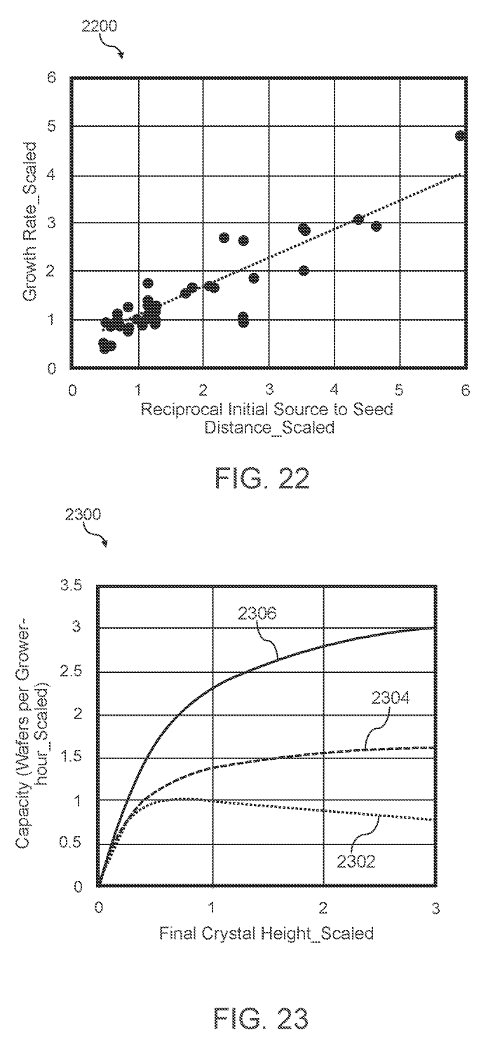

FIG. 22 depicts a plot 2200 showing increased growth rates that may be achievable as a result of relative positioning according to examples of the present disclosure. FIG. 22 plots normalized reciprocal initial source to seed distance on the horizontal axis and normalized growth rate along the vertical axis. As demonstrated, larger source to seed distance, to accommodate growing taller crystals, leads to reduced growth rate. However, as discussed above, relative positioning according to examples of the present disclosure allows for growing taller crystals with reduced initial source to seed distance. Accordingly, aspects of the present disclosure may lead to increased growth rates of crystalline material.

FIG. 23 depicts a plot 2300 showing wafer capacity for a crystal growth system as a function of crystal height. FIG. 23 plots normalized crystal height along the horizontal axis and capacity in wafers per hour per crystal grower on the vertical axis. Curve 2302 demonstrates a reduction in capacity as crystal height increases, primarily due to the reduction growth rate for accommodating larger crystal heights without implementing relative positioning according to examples of the present disclosure. However, curves 2304 and 2306 (each associated with a different growth rate) demonstrate the continued increase in capacity as a function of increased crystal height when implementing relative positioning according to example embodiments of the present disclosure.

For any of the crystal growth systems provided herein, one or more parts of the crystal growth system or the source material may be 3D printed, such as disclosed in U.S. Application Serial No. 18/963,082, which is incorporated herein by reference. For instance, in some embodiments, the 3D printed source may include a silicon carbide powder and a binder (e.g., UV curable polymer adhesive). In some embodiments, the 3D printed part may include a ceramic material (e.g., silicon carbide, metal mixed with carbon, etc.) and a binder (e.g., UV curable polymer adhesive).

Example aspects of the present disclosure are set forth below. Any of the below features or examples may be used in combination with any of the embodiments or features provided in the present disclosure.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material during the crystal growth process, the growth face comprising a dimension of about 100 mm. In some implementations, the example crystalline material includes imparting relative positioning of the growth face of the crystalline material within the crucible during the crystal growth process.

In some implementations of the example method, imparting relative positioning of the growth face of the crystalline material includes moving at least one of a seed holder holding the crystalline material or the source material.

In some implementations of the example method, imparting relative positioning of the growth face of the crystalline material includes moving the source material relative to the growth face of the crystalline material.

In some implementations of the example method, imparting relative positioning of the growth face of the crystalline material includes moving a seed holder holding the crystalline material relative to the source material.

In some implementations of the example method, imparting relative positioning of the growth face of the crystalline material during the crystal growth process includes maintaining a constant mass transport distance between the source material and the growth face during the crystal growth process.

In some implementations of the example method, imparting relative positioning of the growth face of the crystalline material during the crystal growth process includes providing a variable mass transport distance between the source material and the growth face during the crystal growth process.

In some implementations of the example method, imparting relative positioning of the growth face of the crystalline material during the crystal growth process includes maintaining the growth face at a position of selected mass transport flux during the crystal growth process.

In some implementations of the example method, imparting relative positioning of the growth face of the crystalline material during the crystal growth process includes maintaining the growth face at a position of selected temperature in the crucible.

In some implementations of the example method, the crystal growth system includes an interface structure between the growth face and the source material.

In some implementations of the example method, the interface structure includes a baffle structure.

In some implementations of the example method, the interface structure includes a secondary source material.

In some implementations of the example method, the interface structure includes graphite.

In some implementations of the example method, imparting relative positioning of the growth face of the crystalline material during the crystal growth process includes moving at least one of a seed holder holding the crystalline material or the source material relative to the interface structure.

In some implementations of the example method, imparting relative positioning of the growth face of the crystalline material during the crystal growth process includes moving the interface structure relative to the source material or a seed holder holding the crystalline material.

In some implementations of the example method, the crucible includes a first portion, a second portion and a bearing surface between the first portion and the second portion.

In some implementations of the example method, the growth face is in the first portion of the crucible, wherein the source material is in the second portion of the crucible.

In some implementations of the example method, the bearing surface implements a mass transport restriction out of the crucible such that a loss of the crystal growth process is less than about 20%.

In some implementations of the example method, the bearing surface is a linear bearing surface.

In some implementations of the example method, the crystal growth system includes one or more heaters, wherein adjusting a position of the source material further includes providing a defined distance between the growth face and the one or more heaters during the crystal growth process.

In some implementations of the example method, the crystal growth system includes one or more insulation structures, wherein adjusting a position of the source material includes providing a defined distance between the growth face and the one or more insulation structures.

In some implementations of the example method, the crystal growth processes etches the source material.

In an aspect, the present disclosure provides an example crystalline material, the crystalline material comprising silicon carbide. The system includes a crucible comprising a growth zone for the crystalline material. The system includes a positioning system configured to impart relative positioning of a growth face of the crystalline material relative to a source material within the crucible during a crystal growth process, wherein the growth face comprises a dimension of at least about 100 mm.

In some implementations of the example crystal growth system, the positioning system is configured to move at least one of a seed holder holding the crystalline material or a source material.

In some implementations of the example crystal growth system, the positioning system is configured to move a source material relative to the growth face of the crystalline material.

In some implementations of the example crystal growth system, the positioning system is configured to move a seed holder holding the crystalline material relative to a source material.

In some implementations of the example crystal growth system, the positioning system is configured to maintain a constant mass transport distance between a source material and the growth face during the crystal growth process.

In some implementations of the example crystal growth system, the positioning system is configured to provide a variable mass transport distance between a source material and the growth face during the crystal growth process.

In some implementations of the example crystal growth system, the positioning system is configured maintaining the growth face at a position of selected vapor flux during the crystal growth process.

In some implementations of the example crystal growth system, the positioning system is configured to maintain the growth face at a position of selected temperature in the crucible.

In some implementations of the example crystal growth system, the crystal growth system includes an interface structure between the growth face and a source material, wherein the positioning system is configured to move at least one of a seed holder holding the crystalline material or a source material relative to the interface structure.

In some implementations of the example crystal growth system, the crystal growth system includes an interface structure between the growth face and a source material, wherein the positioning system is configured to move the interface structure.

In some implementations of the example crystal growth system, the crystal growth system includes one or more heaters, wherein the positioning system is configured to provide a defined distance between the growth face and the one or more heaters during the crystal growth process.

In some implementations of the example crystal growth system, the crystal growth system includes one or more insulation structures, wherein the positioning system is configured to provide a defined distance between the growth face and the one or more insulation structures.

In an aspect, the present disclosure provides an example crystalline material. In some implementations, the example crystalline material includes a crucible at least partially defining a crystal growth chamber. In some implementations, the example crystalline material includes a seed holder configured to hold a crystalline material includes a dimension of at least about 100 mm. In some implementations, the example crystalline material includes a source material. In some implementations, the example crystalline material includes an actuator configured to impart relative movement between a growth face of a crystalline material and the source material during a crystal growth process implemented in the crystal growth chamber.

In some implementations of the example crystal growth system, the actuator is configured to move the seed holder.

In some implementations of the example crystal growth system, the actuator is configured to move the source material.

In some implementations of the example crystal growth system, the actuator includes a first actuator configured to move the seed holder and a second actuator configured to move a seed crystal.

In some implementations of the example crystal growth system, the actuator is configured to maintain a constant mass transport distance between the source material and the growth face during the crystal growth process.

In some implementations of the example crystal growth system, the actuator is configured to maintain a variable mass transport distance between the source material and the growth face during the crystal growth process.

In an aspect, the present disclosure provides a crystal growth system for growing a crystalline material. In some implementations, the example crystal growth system includes a crucible at least partially defining a crystal growth chamber for growing crystalline material includes a dimension of at least about 100 mm, the crucible having a first portion and a second portion. In some implementations, the example crystalline material includes a source material in the second portion of the crucible. In some implementations, the example crystalline material includes a bearing surface between the first portion and the second portion to provide for relative movement between the first portion and the second portion during a crystal growth process.

In some implementations of the example crystal growth system, the crystalline material is in the first portion of the crucible.

In some implementations of the example crystal growth system, the bearing surface implements a mass transport restriction out of the crucible such that a loss of the crystal growth process is less than about 20%.

In some implementations of the example crystal growth system, the bearing surface is a linear bearing surface.

In some implementations of the example crystal growth system, the system further includes an actuator configured to impart relative movement between the first portion and the second portion.

In some implementations of the example crystal growth system, the actuator includes a first actuator configured to move the first portion.

In some implementations of the example crystal growth system, the actuator includes a second actuator configured to move the second portion.

In an aspect, the present disclosure provides an example crystalline material. In some implementations, the example crystalline material includes a crucible at least partially defining a crystal growth chamber, the crucible comprising a first zone and a second zone. In some implementations, the example crystalline material includes an interface structure between the first zone and the second zone in the crystal growth chamber. In some implementations, the example crystalline material includes an actuator configured to impart relative movement between a growth face of the crystalline material relative and the interface structure.

In some implementations of the example crystal growth system, the interface structure includes a baffle structure.

In some implementations of the example crystal growth system, the interface structure includes a secondary source material.

In some implementations of the example crystal growth system, the interface structure includes graphite.

In some implementations of the example crystal growth system, the actuator is configured to move at least one of a seed holder holding the crystalline material or a source material relative to the interface structure.

In some implementations of the example crystal growth system, the actuator is configured to move the interface structure relative to a source material or a seed holder holding the crystalline material.

In an aspect, the present disclosure provides an example crystalline material. In some implementations, the example crystalline material includes a crucible at least partially defining a crystal growth chamber. In some implementations, the example crystalline material includes a seed holder configured to hold a crystalline material includes a dimension of at least about 100 mm. In some implementations, the example crystalline material includes a source material. In some implementations, the example crystalline material includes an actuator configured to move the seed holder to maintain a growth face of the crystalline material at a defined position within the crucible during a crystal growth process.

In some implementations of the example crystal growth system, the actuator is configured to move the crystalline material during the crystal growth process.

In some implementations of the example crystal growth system, the actuator is configured to maintain the growth face at a position of selected vapor flux during the crystal growth process.

In some implementations of the example crystal growth system, the actuator is configured to maintain the growth face at a position of selected temperature in the crucible.

In some implementations of the example crystal growth system, the actuator is configured to provide a defined distance between the growth face and one or more heaters during the crystal growth process.

In some implementations of the example crystal growth system, the actuator is configured to provide a defined distance between the growth face and one or more insulation structures during the crystal growth process.

In some implementations of the example crystal growth system, the system further comprises an interface structure between the seed holder and the source material.

In some implementations of the example crystal growth system, the actuator is configured to maintain a defined distance between the growth face and the interface structure during the crystal growth process.

In some implementations of the example crystal growth system, the actuator is configured to move the crystalline material relative to the interface structure during the crystal growth process.

In some implementations of the example crystal growth system, the actuator is configured to move the interface structure relative to the crystalline material during the crystal growth process.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material at a first relative position in the crystal growth system. In some implementations, the example crystalline material includes imparting relative positioning of the growth face of the crystalline material to a second relative position within the crystal growth system different from the first relative position to impart a change in the growth process on the crystalline material.

In some implementations of the example method, the method further includes imparting relative positioning of the growth face of the crystalline material to the first relative position for a third process period, the third process period occurring after the first process period and the second process period.

In some implementations of the example method, the first position is associated with a first temperature.

In some implementations of the example method, the second position is associated with a second temperature that is different from the first temperature.

In some implementations of the example method, imparting relative positioning of the growth face of the crystalline material includes moving a seed holder holding the crystalline material relative to the source material.

In some implementations of the example method, the crystal growth system includes an interface structure between the growth face and the source material.

In some implementations of the example method, imparting relative positioning of the growth face of the crystalline material during the crystal growth process includes moving the interface structure relative to the source material or a seed holder holding the crystalline material.

In some implementations of the example method, the crucible includes a first portion, a second portion and a bearing surface between the first portion and the second portion.

In some implementations of the example method, the growth face is in the first portion of the crucible, wherein the source material is in the second portion of the crucible.

In some implementations of the example method, the bearing surface implements a mass transport restriction out of the crucible such that a loss of the crystal growth process is less than about 20%.

In some implementations of the example method, the bearing surface is a linear bearing surface.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material during the crystal growth process. In some implementations, the example crystalline material includes imparting relative movement of a seed holder holding the crystalline material at a pulling rate, wherein the pulling rate is based at least in part on a growth rate of the crystalline material.

In some implementations of the example method, the pulling rate is about equal to the growth rate.

In some implementations of the example method, the method includes determining a change in growth rate of the crystalline material during the crystal growth process; and adjusting the pulling rate based on the change in the growth rate of the crystalline material.

In some implementations of the example method, imparting relative movement of the seed holder at a pulling rate maintain a growth face of the crystalline material in about the same position during the crystal growth process.

In an aspect, the present disclosure provides an example crystalline material. In some implementations, the example crystalline material includes heating a source material in a crucible to transport a vapor to a crystalline material in a crystal growth process. In some implementations, the example crystalline material includes providing the vapor at a growth face of the crystalline material to grow crystalline material during the crystal growth process. In some implementations, the example crystalline material includes imparting relative rotational movement of the growth face of the crystalline material within the crucible relative to the source material during the crystal growth process.

In some implementations of the example method, imparting relative rotational movement of the growth face of the crystalline material during the crystal growth process includes imparting rotational movement to a seed holder.

In some implementations of the example method, imparting relative rotational movement of the growth face of the crystalline material during the crystal growth process includes imparting rotational movement to the source material.

In some implementations of the example method, imparting relative rotational movement of the growth face of the crystalline material during the crystal growth process includes imparting first rotational movement to a seed holder and second rotational movement to the source material.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for growing crystalline material in a crystal growth system, the crystalline material comprising silicon carbide, the method comprising:
heating a source material in a crucible to transport a vapor to a crystalline material in a crystal growth process;
providing the vapor at a growth face of the crystalline material to grow crystalline material during the crystal growth process, the growth face comprising a dimension of about 100 mm;
imparting relative positioning of the growth face of the crystalline material within the crucible during the crystal growth process.

2. The method of claim 1, wherein imparting relative positioning of the growth face of the crystalline material comprises moving at least one of a seed holder holding the crystalline material or the source material.

3. The method of claim 1, wherein imparting relative positioning of the growth face of the crystalline material comprises moving the source material relative to the growth face of the crystalline material.

4. The method of claim 1, wherein imparting relative positioning of the growth face of the crystalline material comprises moving a seed holder holding the crystalline material relative to the source material.

5. The method of claim 1, imparting relative positioning of the growth face of the crystalline material during the crystal growth process comprises maintaining a constant mass transport distance between the source material and the growth face during the crystal growth process.

6. The method of claim 1, wherein imparting relative positioning of the growth face of the crystalline material during the crystal growth process comprises providing a variable mass transport distance between the source material and the growth face during the crystal growth process.

7. The method of claim 1, wherein imparting relative positioning of the growth face of the crystalline material during the crystal growth process comprises maintaining the growth face at a position of selected mass transport flux during the crystal growth process.

8. The method of claim 1, wherein imparting relative positioning of the growth face of the crystalline material during the crystal growth process comprises maintaining the growth face at a position of selected temperature in the crucible.

9. The method of claim 1, wherein the crystal growth system comprises an interface structure between the growth face and the source material.

10. The method of claim 9, wherein the interface structure comprises a baffle structure.

11. The method of claim 9, wherein the interface structure comprises a secondary source material.

12. The method of claim 9, wherein the interface structure comprises graphite.

13. The method of claim 9, wherein imparting relative positioning of the growth face of the crystalline material during the crystal growth process comprises moving at least one of a seed holder holding the crystalline material or the source material relative to the interface structure.

14. The method of claim 9, wherein imparting relative positioning of the growth face of the crystalline material during the crystal growth process comprises moving the interface structure relative to the source material or a seed holder holding the crystalline material.

15. The method of claim 1, wherein the crucible comprises a first portion, a second portion and a bearing surface between the first portion and the second portion, wherein the growth face is in the first portion of the crucible, wherein the source material is in the second portion of the crucible.

16. The method of claim 15, wherein the bearing surface implements a mass transport restriction out of the crucible such that a loss of the crystal growth process is less than about 20%.

17. The method of claim 15, wherein the bearing surface is a linear bearing surface.

18. The method of claim 1, wherein the crystal growth system comprises one or more heaters, wherein adjusting a position of the source material further comprises providing a defined distance between the growth face and the one or more heaters during the crystal growth process.

19. The method of claim 1, wherein the crystal growth system comprises one or more insulation structures, wherein adjusting a position of the source material comprises providing a defined distance between the growth face and the one or more insulation structures.

20. The method of claim 1, wherein the crystal growth processes etches the source material.

21. A crystal growth system for growing crystalline material, the crystalline material comprising silicon carbide, the system comprising:
a crucible comprising a growth zone for the crystalline material;
a positioning system configured to impart relative positioning of a growth face of the crystalline material relative to a source material within the crucible during a crystal growth process, wherein the growth face comprises a dimension of at least about 100 mm.

22. A crystal growth system for growing crystalline material, the crystalline material comprising silicon carbide, the crystal growth system comprising:a crucible at least partially defining a crystal growth chamber;
a seed holder configured to hold a crystalline material comprises a dimension of at least about 100 mm;
a source material;
an actuator configured to impart relative movement between a growth face of a crystalline material and the source material during a crystal growth process implemented in the crystal growth chamber.
